(19) United States
(12) Patent Application Publication
(10) Pub. No.: US 2020/0225576 A1
(43) Pub. Date: Jul. 16, 2020

(54) PHOTOSENSITIVE COLORING COMPOSITION AND METHOD OF MANUFACTURING OPTICAL FILTER

(71) Applicant: FUJIFILM Corporation, Tokyo (JP)

(72) Inventors: Takahiro OKAWARA, Haibara-gun (JP); Yuki NARA, Haibara-gun (JP)

(73) Assignee: FUJIFILM Corporation, Tokyo (JP)

(21) Appl. No.: 16/826,531

(22) Filed: Mar. 23, 2020

Related U.S. Application Data
(63) Continuation of application No. PCT/JP2018/034940, filed on Sep. 21, 2018.

(30) Foreign Application Priority Data
Sep. 29, 2017 (JP) 2017-189632

(51) Int. Cl. G03F 7/00; G03F 7/20

(52) U.S. Cl. CPC G03F 7/0007; G03F 7/168; G03F 7/2004

(57) ABSTRACT

Provided is a photosensitive coloring composition with which a pixel having excellent adhesiveness with a support and excellent rectangularity can be formed. In addition, provided is also a method of manufacturing an optical filter including a pixel having excellent adhesiveness with a support and excellent rectangularity. This photosensitive coloring composition is a photosensitive coloring composition for exposure to light having a wavelength of 300 nm or shorter, the photosensitive coloring composition including a coloring material and a curable compound. In a case where a film having a thickness of 0.5 μm after drying is formed using the photosensitive coloring composition, an optical density of the above-described film with respect to light having a wavelength of 248 nm is 1.6 or higher. It is preferable that a content of the coloring material is 50 mass % or higher with respect to a total solid content of the photosensitive coloring composition.

### CROSS-REFERENCE TO RELATED APPLICATIONS

This application is a Continuation of PCT International Application No. PCT/JP2018/034940 filed on Sep. 21, 2018, which claims priority under 35 U.S.C § 119(a) to Japanese Patent Application No. 2017-189632 filed on Sep. 29, 2017. Each of the above application(s) is hereby expressly incorporated by reference, in its entirety, into the present application.

### BACKGROUND OF THE INVENTION

### 1. Field of the Invention

The present invention relates to a photosensitive coloring composition. More specifically, the present invention relates to a photosensitive coloring composition that is exposed to light having a wavelength of 300 nm or shorter for use. In addition, the present invention relates to a method of manufacturing an optical filter in which the photosensitive coloring composition is used.

### 2. Description of the Related Art

In a video camera, a digital still camera, a mobile phone with a camera function, or the like, a solid image pickup element such as a charge coupled device (CCD) or a complementary metal-oxide semiconductor (CMOS) is used. In addition, in the solid image pickup element, an optical filter including a pixel that is formed using a photosensitive coloring composition is used. As the photosensitive coloring composition, a composition including a coloring material and a curable compound is used (refer to JP2012-532334A and JP2010-097172A).

### SUMMARY OF THE INVENTION

Recently, regarding a pixel that is formed of a photosensitive coloring composition, further improvement is required for rectangularity or adhesiveness with a support. Accordingly, an object of the present invention is to provide a photosensitive coloring composition with which a pixel having excellent adhesiveness with a support and excellent rectangularity can be formed. In addition, another object of the present invention is to provide a method of manufacturing an optical filter including a pixel having excellent adhesiveness with a support and excellent rectangularity.

As a result of thorough investigation, the present inventors found that, in a case where a layer formed of a photosensitive coloring composition having a high optical density with respect to light having a wavelength of 248 nm or a layer formed of a photosensitive coloring composition including a large amount of a coloring material is irradiated with light having a wavelength of 300 nm or shorter to form a pixel, surprisingly, a pixel having excellent rectangularity and excellent adhesiveness with a support can be formed, thereby completing the present invention. Accordingly, the present invention provides the following.

<1> A photosensitive coloring composition comprising:
a coloring material; and
a curable compound,
in which the photosensitive coloring composition is used for exposure to light having a wavelength of 300 nm or shorter, and
in a case where a film having a thickness of 0.5 μm after drying is formed using the photosensitive coloring composition, an optical density of the film with respect to light having a wavelength of 248 nm is 1.6 or higher.

<2> The photosensitive coloring composition according to <1>,
in which a content of the coloring material is 50 mass % or higher with respect to a total solid content of the photosensitive coloring composition.

<3> A photosensitive coloring composition comprising;
a coloring material; and
a curable compound,
in which the photosensitive coloring composition is used for exposure to light having a wavelength of 300 nm or shorter, and
a content of the coloring material is 50 mass % or higher with respect to a total solid content of the photosensitive coloring composition.

<4> The photosensitive coloring composition according to any one of <1> to <3>, which is a photosensitive coloring composition for exposure to a KrF ray.

<5> The photosensitive coloring composition according to any one of <1> to <4>,
in which the curable compound includes a polymerizable monomer, and
a polymerizable group value of the polymerizable monomer is 10.5 mmol/g or higher,

<6> The photosensitive coloring composition according to <5>, further comprising:
a photopolymerization initiator.

<7> The photosensitive coloring composition according to <6>,
in which the photopolynterization initiator is at least one compound selected from an alkylphenone compound, an acylphosphine compound, a benzophenone compound, a thioxanthone compound, a triazine compound, a pinacol compound, or an oxime compound.

<8> The photosensitive coloring imposition according to any one of <1> to <7>,
in which the coloring material includes a green colorant.

<9> The photosensitive coloring composition according to <8>,
in which a content of the green colorant is 50 mass % or higher with respect to a total mass of the coloring material.

<10> A method of manufacturing an optical filter, the method comprising:
a step of forming a photosensitive coloring composition layer having an optical density of 1.6 or higher with respect to light having a wavelength of 248 nm on a support using a photosensitive coloring composition including a coloring material and a curable compound;
a step of irradiating the photosensitive coloring composition layer with light having a wavelength of 300 nm or shorter to be exposed in a pattern shape; and
a step of forming a pixel by removing a turn-exposed portion of the photosensitive coloring composition layer by development.

<11> The method of manufacturing an optical filter according to <10>,
in which the exposure step is performed using a KrF scanner exposure device.

<12> The method of manufacturing an optical filter according to <10> or <11>,
in which the photosensitive coloring composition is the photosensitive coloring composition according to any one of <1> to <8>.

According to the present invention, it is possible to provide a photosensitive coloring composition with which a pixel having excellent adhesiveness with a support and excellent rectangularity can be formed. In addition, it is also possible to provide a method of manufacturing an optical filter including a pixel having excellent adhesiveness with a support and excellent rectangularity.

### DESCRIPTION OF THE PREFERRED EMBODIMENTS

Hereinafter, the details of the present invention will be described.

In this specification, numerical ranges represented by “to” include numerical values before and after “to” as lower limit values and upper limit values.

In this specification, unless specified as a substituted group or as an unsubstituted group, a group (atomic group) denotes not only a group (atomic group) having no substituent but also a group (atomic group) having a substituent. For example, “alkyl group” denotes not only an alkyl group having no substituent (unsubstituted alkyl group) but also an alkyl group having a substituent (substituted alkyl group).

In this specification, unless specified otherwise, “exposure” denotes not only exposure using light but also drawing using a corpuscular beam such as an electron beam or an ion beam. Examples of the light used for exposure include an actinic ray or radiation, for example, a bright light spectrum of a mercury lamp, a far ultraviolet ray represented by an excimer laser, an extreme ultraviolet ray (EUV ray), an X-ray, or an electron beam.

In this specification, “(meth)allyl group” denotes either or both of allyl and methallyl. “(meth)acrylate” denotes either or both of acrylate or methacrylate, “(meth)acryl” denotes either or both of acryl and methacryl, and “(meth)acryloyl” denotes either or both of acryloyl and methacryloyl.

In this specification, a weight-average molecular weight and a number-average molecular weight denote values in terms of polystyrene measured by gel permeation chromatography (GPC). GPC can be performed using a method in which HLC-8120 (manufactured by Tosoh Corporation) is used as a GPC device, TSK gel Multipore HXL-M (manufactured by Tosoh Corporation, 7.8 mm ID (Inner Diameter)×30.0 cm) is used as a column, and tetrahydrofuran (THF) is used as an eluent.

In this specification, infrared light denotes light in a wavelength range of 700 to 2500 nm.

In this specification, a total solid content denotes the total mass of all the components of the composition excluding a solvent.

In this specification, the term “step” denotes not only an individual step but also a step which is not clearly distinguishable from another step as long as an effect expected from the step can be achieved.

<Photosensitive Coloring Composition>

A first photosensitive coloring composition according to an embodiment of the present invention comprises:
a coloring material; and
a curable compound.
in which the photosensitive adoring composition is used for exposure to light having a wavelength of 300 nm or shorter, and
in a case where a film having a thickness of 0.5 μm after drying is formed using the photosensitive coloring composition, an optical density of the film with respect to light having a wavelength of 248 nm is 1.6 or higher.

In addition, a second photosensitive coloring composition according to an embodiment of the present invention comprises:
a coloring material; and
a curable compound,
in which the photosensitive coloring composition is used for exposure to light having a wavelength of 300 nm or shorter, and
a content of the coloring material is 50 mass % or higher with respect to a total solid content of the photosensitive coloring composition.

According to the present invention, a pixel having excellent adhesiveness with a support and excellent rectangularity cart be formed. The reason why this effect is obtained is presumed to be as follows. That is, the following is presumed. In the first and second photosensitive coloring compositions, absorption with respect to light having a wavelength of 300 nm or shorter tends to increase. In a case where the photosensitive coloring composition is irradiated with light having a wavelength of 300 nm or shorter to be exposed, the surface layer of the photosensitive coloring composition tends to be more easily cured than the inside thereof. Therefore, even in a case where the photosensitive coloring composition layer formed on the support using a method such as a method of applying the photosensitive coloring composition is irradiated with light having a wavelength of 300 nm or shorter such that the photosensitive coloring composition layer can be sufficiently cured up to the bottom portion, the thickening of the support side of the photosensitive coloring composition layer can be suppressed, and thus a pixel having excellent rectangularity and excellent adhesiveness with the support can be formed.

In a case where a film having a thickness of 0.5 μm after drying is formed using the first photosensitive coloring composition, the optical density of the above-described film with respect to light having a wavelength of 248 nm is preferably 1.8 or higher and more preferably 2.0 or higher. The upper limit is not particularly limited and may be 3.5 or lower. The optical density refers to a value representing the degree of absorption of light using a logarithm that is a value defined by the following expression.

OD(λ)=Log₁₀[T(λ)/I(λ)] λ represents a wavelength. T(λ) represents the amount of transmitted light at the wavelength λ, and I(λ) represents the amount of incidence light at the wavelength λ.

In a case where a film having a thickness of 0.5 μm after drying is formed, the optical density of the film at a wavelength of 248 nm can be adjusted to be 1.6 or higher, for example, using a method such as a method of appropriately adjusting the kind and content of the coloring material or a method of adding an appropriate amount of an additive (for example, an ultraviolet absorber) that absorbs light having a short wavelength.

The photosensitive coloring composition according to the embodiment of the present invention is preferably used as a composition for forming a colored pixel, a black pixel, a light blocking film, a pixel of an infrared transmitting filter layer, or the like. Examples of the colored pixel include a pixel of a color selected from red, blue, green, cyan, magenta, or yellow. Examples of the pixel of the infrared transmitting filter layer include a pixel of a filter layer satisfying spectral characteristics in which a maximum value of a transmittance in a wavelength range of 400 to 640 nm is 20% or lower (preferably 15% or lower and more preferably 10% or lower) and a minimum value of a transmittance in a wavelength range of 1100 to 1300 nm is 70% or higher (preferably 75% or higher and more preferably 80% or higher). In addition, it is also preferable that the pixel of the infrared transmitting filter layer is a pixel of a filter layer satisfying any one of the following spectral characteristics (1) to (4).

(1): a pixel of a filter layer in which a maximum value of a transmittance in a wavelength range of 400 to 640 nm is 20% or lower (preferably 15% or lower and more preferably 10% or lower) and a minimum value of a transmittance in a wavelength range of 800 to 1300 nm is 70% or higher (preferably 75% or higher and more preferably 80% or higher).

(2): a pixel of a filter layer in which a maximum value of a transmittance in a wavelength range of 400 to 750 nm is 20% or lower (preferably 15% or lower and more preferably 10% or lower) and a minimum value of a transmittance in a wavelength range of 900 to 1300 nm is 70% or higher (preferably 75% or higher and more preferably 80% or higher).

(3): a pixel of a filter layer in which a maximum value of a transmittance in a wavelength range of 400 to 830 nm is 20% or lower (preferably 15% or lower and more preferably 10% or lower) and a minimum value of a transmittance in a wavelength range of 1000 to 1300 nm is 70% or higher (preferably 75% or higher and more preferably 80% or higher).

(4): a pixel of a filter layer in which a maximum value of a transmittance m a wavelength range of 400 to 950 nm is 20% or lower (preferably 15% or lower and more preferably 10% or lower) and a minimum value of a transmittance in a wavelength range of 1100 to 1300 nm is 70% or higher (preferably 75% or higher and mote preferably 80% or higher).

In a case where the photosensitive coloring composition according to the embodiment of the present invention is used as a composition for forming a pixel of an infrared transmitting filter layer, it is preferable that the photosensitive coloring composition according to the embodiment of the present invention satisfies spectral characteristics in which a ratio Amin/Bmax of a minimum value Amin of an absorbance of the composition in a wavelength range of 400 to 640 nm to a maximum value Bmax of an absorbance of the composition in a wavelength range of 1100 to 1300 nm is 5 or higher. Amin/Bmax is more preferably 7.5 or higher, still more preferably 15 or higher, and still more preferably 30 or higher.

An absorbance Aλ at a wavelength λ is defined by the following Expression (1).

Aλ=−log(Tλ/100) (1)

Aλ is an absorbance at the wavelength λ and Tλ is a transmittance (%) at the wavelength λ.

In the present invention, a value of the absorbance may be a value measured in the form of a solution or a value of a film which is formed using the photosensitive coloring composition. In a case where the absorbance is measured in the form of the film, it is preferable that the absorbance is measured using a film that is formed by applying the photosensitive coloring composition to a glass substrate using a method such as spin coating such that the thickness of the dried film is a predetermined value, and drying the applied composition using a hot plate at 100° C. for 120 seconds. The thickness of the film can be obtained by measuring the thickness of the substrate including the film using a stylus surface profilometer (DEKTAK 150, manufactured by ULVAC Inc.).

In a case where the photosensitive coloring composition according to the embodiment of the present invention is used as a composition for forming a pixel of an infrared transmitting filter layer, it is more preferable that the photosensitive coloring composition according to the embodiment of the present invention satisfies any one of the following spectral characteristics (11) to (14).

(11): A ratio Amin1/Bmax1 of a minimum value Amin1 of an absorbance of the near infrared transmitting filter-forming composition in a wavelength range of 400 to 640 nm to a maximum value Bmax1 of an absorbance of the near infrared transmitting filter-forming composition in a wavelength range of 800 to 1300 nm is 5 or higher, preferably 7.5 or higher, more preferably 15 or higher, and still more preferably 30 or higher. In this aspect, a film that can block light in a wavelength range of 400 to 640 nm and allows transmission of light having a wavelength of 720 nm or longer can be formed.

(12): A ratio Amin2/Bmax2 of a minimum value Amin2 of an absorbance of the near infrared transmitting filter-forming composition in a wavelength range of r00 to 750 nm to a maximum value Bmax2 of an absorbance of the near infrared transmitting filter-forming composition in a wavelength range of 900 to 1300 nm is 5 or higher, preferably 7.5 or higher, more preferably 15 or higher, and still more preferably 30 or higher. In this aspect, a film that can block light in a wavelength range of 400 to 750 nm and allows transmission of light having a wavelength of 850 nm or longer can be formed.

(13): A ratio Amin3/Bmax3 of a minimum value Amin3 of an absorbance of the near infrared transmitting filter-forming composition in a wavelength range of 400 to 850 nm to a maximum value Bmax3 of an absorbance of the near infrared transmitting filter-forming composition in a wavelength range of 1000 to 1300 nm is 5 or higher, preferably 7.5 or higher, more preferably 15 or higher, and still more preferably 30 or higher. In this aspect, a film that can block light in a wavelength range of 400 to 830 nm and allows transmission of light having a wavelength of 940 nm or longer can be formed.

(14): A ratio Amin4/Bmax4 of a minimum value Amin4 of an absorbance of the near infrared transmitting filter-forming composition in a wavelength range of 400 to 950 nm to a maximum value Bmax4 of an absorbance of the near infrared transmitting filter-forming composition in a wavelength range of 1100 to 1300 nm is 5 or higher, preferably 7.5 or higher, more preferably 15 or higher, and still more preferably 30 or higher. In this aspect, a film that can block light in a wavelength range of 400 to 950 nm and allows transmission of light having a wavelength of 1040 nm or longer can be formed.

Hereinafter, each of the components used in the photosensitive coloring composition according to the embodiment of the present invention will be described.

«Coloring Material»

The photosensitive coloring composition according to the embodiment of the present invention includes a coloring material. Examples of the coloring material include a chromatic colorant, a black colorant, and an infrared absorbing colorant. It is preferable that the coloring material used in the photosensitive coloring composition according to the embodiment of the present invention includes at least a chromatic colorant, and from the viewpoint of increasing the optical density of the film with respect to light having a wavelength of 248 nm, it is more preferable that the coloring material includes a green colorant.

(Chromatic Colorant)

Examples of the chromatic colorant include a red colorant, a green colorant, a blue colorant, a yellow colorant, a violet colorant, and an orange colorant. As the chromatic colorant, a pigment or a dye may be used. It is preferable that the chromatic colorant is a pigment. An average panicle size (r) of the pigment satisfies preferably 20 nm≤r≤300 nm, more preferably 25 nm≤r≤250 nm, and still more preferably 30 nm≤r≤200 nm. “Average particle size” described herein denotes the average particle size of secondary panicles which are aggregates of primary particles of the pigment. In addition, regarding a particle size distribution of the secondary particles of the pigment (hereinafter, simply referred to as “panicle size distribution”) which can be used, secondary panicles having a particle size of (average particle size±100) nm account for preferably 70 mass % or higher and more preferably 80 mass % or higher in the pigment.

As the pigment, an organic pigment is preferable. Preferable examples of the organic pigment are as follows:

Color Index (C.I.) Pigment Yellow 1, 2, 3, 4, 5, 6, 10, 11, 12, 13, 14, 15, 16, 17, 18, 20, 24, 31, 32, 34, 35, 35:1, 36, 36:1, 37, 37:1, 40, 42, 43, 53, 55, 60, 61, 62, 63, 65, 73, 74, 77, 81, 83, 86, 93, 94, 95, 97, 98, 100, 101, 104, 106, 108, 109, 110, 113, 114, 115, 116, 117, 118, 119, 120, 123, 125, 126, 127, 128, 129, 137, 138, 139, 147, 148, 150, 151, 152, 153, 154, 155, 156, 161, 162, 164, 166, 167, 168, 169, 170, 171, 172, 173, 174, 175, 176, 177, 179, 180, 181, 182, 185, 187, 188, 193, 194, 199, 213, and 214 (all of which are yellow pigments);

C.I. Pigment Orange 2, 5, 13, 16, 17:1, 31, 34, 36, 38, 43, 46, 48, 49, 51, 52, 55, 59, 60, 61, 62, 64, 71, and 73 (all of which are orange pigments);

C.I. Pigment Red 1, 2, 3, 4, 5, 6, 7, 9, 10, 14, 17, 22, 23, 31, 38, 41, 48:1, 48:2, 48:3, 48:4, 49, 49:1, 49:2, 52:1, 52:2, 53:1, 57:1, 60:1, 63:1, 66, 67, 81:1, 81:2. 81:3, 83, 88, 90, 105, 112, 119, 122, 123, 144, 146, 149, 150, 155, 166, 168, 169, 170, 171, 172, 175, 176, 177, 178, 179, 184, 185, 187, 188, 190, 200, 202, 206, 207, 208, 209, 210, 216, 220, 224, 226, 242, 246, 254, 255, 264, 270, 272, and 279 (all of which are red pigments);

C.I. Pigment Green 7, 10, 36, 37, 58, and 59 (all of which are green pigments);

C.I. Pigment Violet 1, 19, 23, 27, 32, 37, and 42 (all of which are violet pigments); and

C.I. Pigment Blue 1, 2, 15, 15:1, 15:2, 15:3, 15:4, 15:6, 16, 22, 60, 64, 66, 79, and 80 (all of which are blue pigments).

Among these organic pigments, one kind may be used alone, or two or more kinds may be used in combination.

As the dye, well-known dyes can be used without any particular limitation. For example, a dye such as a pyrazole azo dye, an anilino azo dye, a triarylmethane dye, an anthraquinone dye, an anthrapyridone dye, a benzylidene dye, an oxonol dye, a pyrazolotriazole azo dye, a pyridone azo dye, a cyanine dye, a phenothiazine dye, a pyrrolopyrazole azomethine dye, a xanthene dye, a phthalocyanine dye, a benzopyran dye, an indigo dye, or a pyrromethene dye can be used. In addition, a polymer of the above-described dyes may be used. In addition, dyes described in JP2015-028144A and JP2015-034966A can also be used.

(Black Colorant)

Examples of the black colorant include an inorganic black colorant such as carbon black, a metal oxynitride (for example, titanium black), or a metal nitride (for example, titanium nitride) and an organic black colorant such as a bisbenzofuranone compound, an azomethine compound, a perylene compound, or an azo compound. As the organic black colorant, a bisbenzofuranone compound or a perylene compound is preferable. Examples of the bisbenzofuranone compound include a compound described in JP2010-534726A, JP2012-515233A, and JP2012-515234A. For example, “Irgaphor Black” (manufactured by BASF SE) is available. Examples of the perylene compound include C.I. Pigment Black 31 and 32. Examples of the azomethine compound include compounds described in JP1989-170601A (JP-HM70601A) and JP1990-034664A (JP H2-034664A). For example, “CHROMOFINE BLACK A1103” (manufactured by Dainichiseika Color & Chemicals Mfg. Co., Ltd.) is available. It is preferable that the bisbenzofuranone compound is one of the following compounds represented by the following formulae or a mixture thereof.

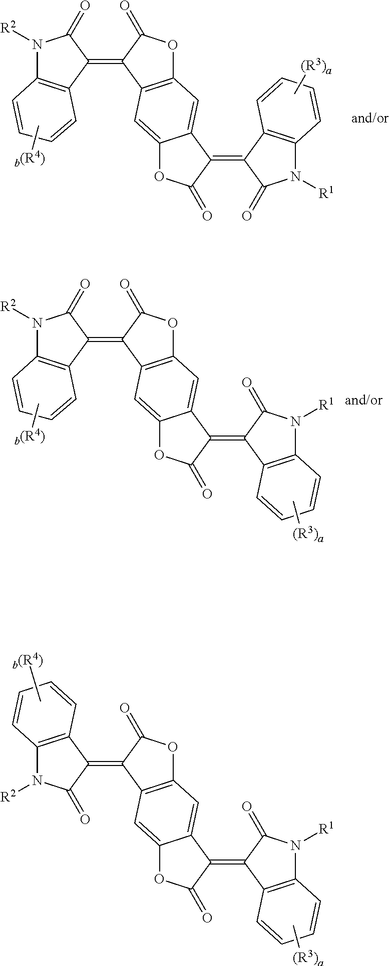

In the formulae, R¹ and R² each independently represent a hydrogen atom or a substituent, R³ and R⁴ each independently represent a substituent, a and b each independently represent an integer of 0 to 4, in a case where a is 2 or more, a plurality of R³'s may be the same as or different from each other, a plurality of R³'s may be bonded to each other to form a ring, in a case where b is 2 or more, a plurality of R⁴'s may be the same as or different from each other, and a plurality of R⁴'s may be bonded to each other to form a ring.

The substituent represented by R¹ to R⁴ is a halogen atom, a cyano group, a nitro group, an alkyl group, an alkenyl group, an alkynyl group, an aralkyl group, an aryl group, a heteroaryl group, —OR³⁰¹, —COR³⁰², —COOR³⁰³, —OCOR³⁰⁴, —NR³⁰⁵R³⁰⁶, —NHCOR³⁰⁷, —CONR³⁰⁸R³⁰⁹, —NHCONR³¹⁰R³¹¹, —NHCOOR³¹², —SR³¹³, —SO₂R³¹⁴, —SO₂OR³¹⁵, —NHSO₂R³¹⁶, or —SO₂NR³¹⁷R³¹⁸. R³⁰¹ to R³¹⁸ each independently represent a hydrogen atom, an alkyl group, an alkenyl group, an alkynyl group, an aryl group, or a heteroaryl group.

The details of the bisbenzofuranone compound can be found in paragraphs “0014” “0037” of JP2010-534726A. the content of which is incorporated herein by reference.

(Infrared Absorbing Colorant)

As the infrared absorbing colorant, a compound having a maximum absorption wavelength preferably in a wavelength range of 700 to 1300 nm and more preferably in a wavelength range of 700 to 1000 nm is preferable. The infrared absorbing colorant may be a pigment or a dye.

In the present invention, as the infrared absorbing colorant, a compound that includes a π-conjugated plane having a monocyclic or fused aromatic ring can be preferably used. The number of atoms constituting the π-conjugated plane included in the infrared absorbing colorant other than hydrogen is preferably 14 or more, more preferably 20 or more, still more preferably 25 or more, and still more preferably 30 or more. For example, the upper limit is preferably 80 or less and more preferably 50 or less. The number of monocyclic or fused aromatic rings in the π-conjugated plane included in the infrared absorbing colorant is preferably 2 or more, more preferably 3 or more, still more preferably 4 or more, and still more preferably 5 or more. The upper limit is preferably 100 or less, more preferably 50 or less, and still more preferably 30 or less. Examples of the aromatic ring include a benzene ring, a naphthalene ring, a pentalene ring, an indene ring, an azulene ring, a heptalene ring, an indacene ring, a perylene ring, a pentacene ring, a quaterrylene ring, an acenaphthene ring, a phenanthrene ring, an anthracene ring, a naphthacene ring, a chrysene ring, a triphenylene ring, a fluorene ring, a pyridine ring, a quinoline ring, an isoquinoline ring, an imidazole ring, a benzimidazole ring, a pyrazole ring, a thiazole ring, a benzothiazole ring, a triazole ring, a benzotriazole ring, an oxazole ring, a benzoxazole ring, an imidazoline ring, a pyrazine ring, a quinoxaline ring, a pyrimidine ring, a quinazolinc ring, a pyridazine ring, a triazine ring, a pyrrole ring, an indole ring, an isoindole ring, a carbazole ring, and a fused ring including the above-described ring.

As the infrared absorbing colorant, at least one selected from a pyrrolopyrroic compound, a cyanine compound, a squarylium compound, a phthalocyanine compound, a naphthalocyanine compound, a quaterrylene compound, a merocyanine compound, a croconium compound, an oxonol compound, a diimmonium compound, a dithiol compound, a triarylmethane compound, a pyrromethene compound, an azomethine compound, an anthraquinone compound, or a dibenzofuranone compound is preferable, at least one selected from a pyrrolopyrrole compound, a cyanine compound, a squarylium compound, a phthalocyanine compound, a naphthalocyanine compound, or a diimmonium compound is more preferable, at least one selected from a pyrrolopyrrole compound, a cyanine compound, a squarylium compound is still more preferable, and a pyrrolopyrrole compound is still more preferable. Examples of the diimmonium compound include a compound described in JP2008-528706A, the content of which is incorporated herein by reference. Examples of the phthalocyanine compound include a compound described in paragraph “0093” of JP2012-077153A, oxytitaniumphthalocyanine described in JP2006-343631A, and a compound described m paragraphs “0013” to “0029” of JP2013-195480A, the contents of which are incorporated herein by reference. Examples of the naphthalocyanine compound include a compound described in paragraph “0093” of JP2012-077153A, the content of which is incorporated herein by reference. In addition, as the cyanine compound, the phthalocyanine compound, the naphthalocyanine compound, the diimmonium compound, or the squarylium compound, for example, a compound described in paragraphs “0010” to “0081” of JP2010-111750A may be used, the content of which is incorporated herein by reference. In addition, the details of the cyanine compound can be found in. for example, “Functional Colorants by Makoto Okawara, Masaru Matsuoka, Teijiro Kitao, and Tsuneoka Hiroshima, published by Kodansha Scientific Ltd.”, the content of which is incorporated herein by reference. In addition, a compound described in paragraphs JP2016-146619A can also be used as the infrared absorbing compound, the content of which is incorporated herein by reference.

Examples of the pyrrolopyrrole compound include compounds described in paragraphs “0016” to “0058” of JP2009-263614A, compounds described in paragraphs “0037” to “0052” of JP2011-068731A, compounds described in paragraphs “0010” to “0033” of WO2015/166873A, the contents of which are incorporated herein by reference.

Examples of the squarylium compound include n compound described in paragraphs “0044” to “0049” of JP2011-208101A, a compound described in paragraphs “0060” and “0061” of JP6065169B, a compound described in paragraph “0040” of WO2016/181987A, a compound described in WO2013/133099A, a compound described in WO2014/088063A, a compound described in JP2014-126642A, a compound described in JP2016-146619A, a compound described in JP2015-176046A, a compound described in JP2017-025311A, a compound described in WO2016/154782A, a compound described in JP5884953B. a compound described in JP6036689B, a compound described in JP5810604B, and a compound described in JP2017-068120A, the contents of which are incorporated herein by reference.

In addition, examples of the cyanine compound include a compound described in paragraphs “0044” and “0045” of JP2009-108267A, a compound described in paragraphs “0026” to “0030” of JP2002-194040, a compound described in JP2015-172004A, a compound described in JP2015-172102A, a compound described in JP2008-088426A, and a compound described in JP2017-031394A, the contents of which are incorporated herein by reference.

In the present invention, as the infrared absorbing colorant, a commercially available product can also be used. Examples of the commercially available product include SDO-C33 (manufactured by Arimoto Chemical Co., Ltd.); EXCOLOR IR-14, EXCOLOR IR-10A, EXCOLOR TX-EX-801B, and EXCOLOR TX-EX-805K (manufactured by Nippon Shokubai Co.. Ltd.); Shigenox NIA-8041, Shigenox NIA-8042, Shigenox NIA-814. Shigenox NIA-820, and Shigenox NIA-839 (manufactured by Hakkol Chemical Co., Ltd.); Epolite V-63, Epolight 3801, and Epolight3036 (manufactured by Epolin Inc.); PRO-JET 825LDI (manufactured by Fujifilm Corporation); NK-3027 and NK-5060 (manufactured by Hayashibara Co., Ltd,); and YKR-3070 (manufactured by Mitsui Chemicals, Inc.).

The content of the coloring material is preferably 50 mass % or higher, more preferably 54 mass % or higher, and still more preferably 58 mass % or higher with respect to the total solid content of the photosensitive coloring composition. In a case where the content of the coloring material is 50 mass % or higher, a pixel having excellent adhesiveness with the support and excellent rectangularity is likely to be formed. Further, a thin pattern having excellent spectral characteristics is likely to be formed, lire upper limit is preferably 80 mass % or lower, more preferably 75 mass % or lower, and still more preferably 70 mass % or lower.

It is preferable that the coloring material used in the photosensitive coloring composition according to the embodiment of the present invention includes at least one selected from a chromatic colorant or a black colorant. In addition, the content of the chromatic colorant and the black colorant is preferably 30 mass % or higher, more preferably 50 mass % or higher, and still more preferably 70 mass % or higher with respect to the total mass of the coloring material. Tire upper limit may be 100 mass % or may be 90 mass % or lower.

In addition, it is preferable that the coloring material used in the photosensitive coloring composition according to the embodiment of the present invention includes at least a green colorant. In addition, the content of the green colorant is preferably 30 mass % or higher, more preferably 40 mass % or higher, and still more preferably 50 mass % or higher with respect to the total mass of the coloring material. The upper limit may be 100 mass % or may be 75 mass % or lower.

In the coloring material used in the photosensitive coloring composition according to the embodiment of the present invention, the content of the pigment is preferably 50 mass % or higher, more preferably 70 mass % or higher, and still more preferably 90 mass % or higher with respect to the total mass of the coloring material.

In a case where the photosensitive coloring composition according to the embodiment of the present invention is used as a composition for forming a colored pixel, the content of the chromatic colorant is preferably 50 mass % or higher, more preferably 54 mass % or higher, and still more preferably 58 mass % or higher with respect to the total solid content of the photosensitive coloring composition. In addition, the content of the chromatic colorant is preferably 25 mass % or higher, more preferably 45 mass % or higher, and still more preferably 65 mass % or higher with respect to the total mass of the coloring material. The upper limit may be 100 mass % or may be 75 mass % or lower. In addition, it is preferable that the coloring material includes at least a green colorant. In addition, the content of the green colorant is preferably 35 mass % or higher, more preferably 45 mass % or higher, and still more preferably 55 mass % or higher with respect to the total mass of the coloring material. The upper limit may be 100 mass % or may be 80 mass % or lower.

In a case where the photosensitive coloring composition according to the embodiment of the present invention is used as a composition for forming a black pixel or a light blocking film, the content of the black colorant (preferably the inorganic black colorant) is preferably 50 mass % or higher, more preferably 54 mass % or higher, and still more preferably 58 mass % or higher with respect to the total solid content of the photosensitive coloring composition. In addition, the content of the black colorant is preferably 30 mass % or higher, more preferably 50 mass % or higher, and still more preferably 70 mass % or higher with respect to the total mass of the coloring material. The upper limit may be 100 mass % or may be 90 mass % or lower.

In a case where the photosensitive coloring composition according to the embodiment of the present invention is used as a composition for forming a pixel of an infrared transmitting filter layer, it is preferable that the coloring material used in the present invention satisfies at least one of the following requirements (1) to (3).

(1): The coloring material that blocks visible light includes two or more chromatic colorants, and a combination of the two or more chromatic colorants forms black That is, it is preferable that the coloring material forms black using a combination of two or more colorants selected from a red colorant, a blue colorant, a yellow colorant, a violet colorant, and a green colorant.

(2): The coloring material includes an organic black colorant.

(3): in (1) or (2), the coloring material further includes an infrared absorbing colorant.

Examples of a preferable combination in the aspect (1) are as follows.

(1-1) An aspect in which the coloring material includes a red colorant and a blue colorant

(1-2) An aspect in which the coloring material includes a red colorant, a blue colorant, and a yellow colorant.

(1-3) An aspect in which the coloring material includes a red colorant a blue colorant, a yellow colorant, and a violet colorant.

(1-4) An aspect in which the coloring material includes a red colorant, a blue colorant, a yellow colorant, a violet colorant, and a green colorant.

(1-5) An aspect in which the coloring material includes a red colorant, a blue colorant, a yellow colorant, and a green colorant.

(1-6) An aspect in which the coloring material includes a red colorant, a blue colorant, and a green colorant.

(1-7) An aspect in which the coloring material includes a yellow colorant and a violet colorant

In the aspect (2), it is preferable that the coloring material further includes a chromatic colorant. By using the organic black colorant in combination with a chromatic colorant, excellent spectral characteristics are likely to be obtained. Examples of the chromatic colorant which can be used in combination with the organic black colorant include a red colorant, a blue colorant, and a violet colorant. Among these, a red colorant or a blue colorant is preferable. Among these colorants, one kind may be used alone, or two or more kinds may be used in combination. In addition, regarding a mixing ratio between the chromatic colorant and the organic black colorant, the amount of the chromatic colorant is preferably 10 to 200 parts by mass and more preferably 15 to 150 parts by mass with respect to 100 parts by mass of the organic black colorant.

In the aspect (3), the content of the infrared absorbing colorant is preferably 5 to 40 mass % with respect to the total mass of the coloring material. The upper limit is preferably 30 mass % or lower and more preferably 25 mass % or lower. The lower limit is preferably 10 mass % or higher and more preferably 15 mass % or higher.

«Curable Compound»

The photosensitive coloring composition according to the embodiment of the present invention includes a curable compound. Examples of the curable compound include a polymerizable monomer, a compound having a cyclic ether group, and a resin. The resin may be a non-polymerizable resin (resin not having a polymerizable group) or a polymerizable resin (resin having a polymerizable group). Examples of the polymerizable group include an ethylenically unsaturated bond group such as a vinyl group, a (meth)allyl group, or a (meth)acryloyl group.

(Polymerizable Monomer)

The polymerizable monomer is preferably a compound having 3 or more polymerizable groups (preferably ethylenically unsaturated bond groups), more preferably a compound having 3 to 15 polymerizable groups, still more preferably a compound having 3 to 10 polymerizable groups, and still more preferably a compound having 3 to 6 polymerizable groups. Specifically, the polymerizable monomer is preferably a (meth)acrylate compound having 3 to 15 functional groups, more preferably a (meth)acrylate compound having 3 to 15 functional groups, still more preferably a (meth)acrylate compound having 3 to 10 functional groups, and still more preferably a (meth)acrylate compound having 3 to 6 functional groups. Specific examples of the polymerizable monomer include compounds described in paragraphs “0095” to “0108” of JP2009-288705A, paragraph “0227” of JP2013-29760 and paragraphs “0254” to “0257” of JP2008-292970A, the contents of which are incorporated herein by reference.

The molecular weight of the polymerizable monomer is preferably 100 to 3000. The upper limit is preferably 2000 or lower and more preferably 1500 or lower. The lower limit is preferably 150 or higher and more preferably 250 or higher.

The polymerizable group value of the polymerizable monomer is preferably 10.0 mmol/g or higher, more preferably 10.5 mmol/g or higher, and still more preferably 11.0 mmol/g or higher. The upper limit is preferably 15 mmol/g or lower. In a case where the polymerizable group value of the polymerizable monomer is 10.0 mmol/g or higher, the photocuring properties of the photosensitive coloring composition is excellent. The polymerizable group value of the polymerizable monomer can be calculated by dividing the number of polymerizable groups in one molecule of the polymerizable monomer by the molecular weight of the polymerizable monomer.

In addition, in a case where the polymerizable monomer is a monomer having an ethylenically unsaturated bond group, the ethylenically unsaturated bond group value (hereinafter, also referral to as “C═C value”) of the polymerizable monomer is preferably 10.0 mmol/g or higher, more preferably 10.5 mmol/g or higher, and still more preferably 11.0 mol/g or higher. The upper limit is preferably 15 mmol/g or lower. The C═C value of the polymerizable monomer can be calculated by dividing the number of ethylenically unsaturated bond groups in one molecule of the polymerizable monomer by the molecular weight of the polymerizable monomer.

As the polymerizable monomer, compounds represented by the following Formulae (MO-1) to (MO-6) can also be preferably used. In a case where T in the formulae represents an oxyalkylene group, a terminal thereof on a carbon atom side is bonded to R.

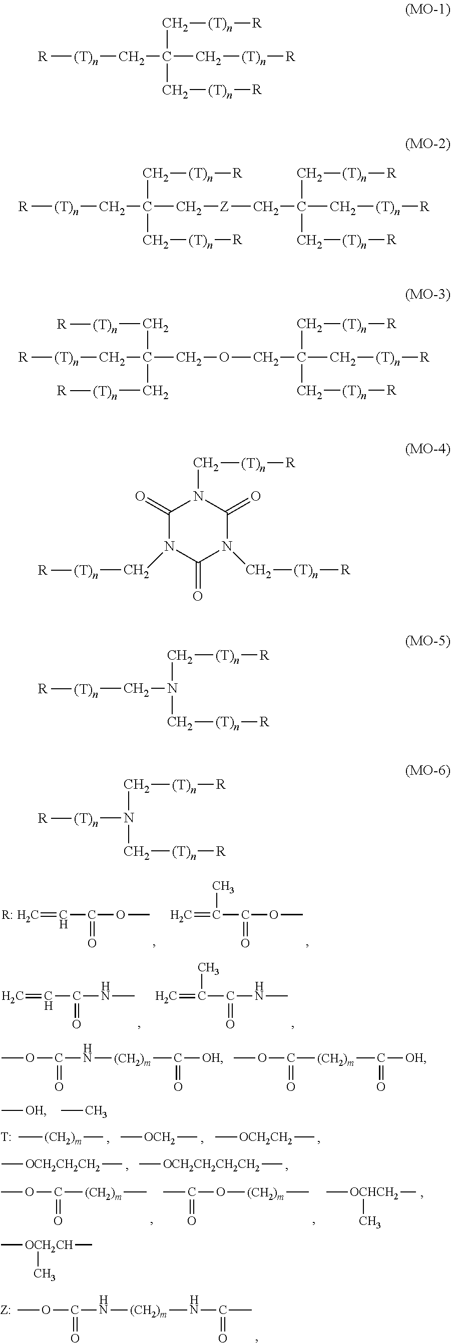

In the formulae, n represents 0 to 14, and m represents 1 to 8. A plurality of R's and a plurality of T's which are present in one molecule may be the same as or different from each other.

At least one of a plurality of R's which are present in each of the compounds represented by Formula (MO-1) to (MO-6) represents —OC(═O)CH═CH₂, —OC(═O)C(CH₃)═CH₂, —NHC(═O)CH═CH₂, or —NHC(═O)C(CH₃)═CH₂.

Specific examples of the polymerizable compounds represented by Formulae (MO-1) to (MO-6) include compounds described in paragraphs “0248” to “0251” of JP2007-269779A.

It is also preferable that the polymerizable monomer is a compound having a caprolactone structure. As the compound having a caprolactone structure, a compound represented by the following Formula (Z-1) is preferable.

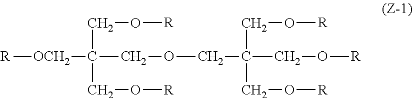

In Formula (Z-1), all of six R's represent a group represented by Formula (Z-2), or one to five R's among the six R's represent a group represented by Formula (Z-2) and the remaining R's represent a group represented by Formula (Z-3), an acid group, or a hydroxy group.

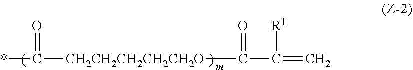

In Formula (2-2), R¹ represents a hydrogen atom or a methyl group, m represents an integer of 1 or 2, and “*” represents a direct bond.

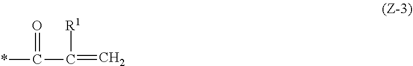

In Formula (Z-3), R¹ represents a hydrogen atom or a methyl group, and “*” represents a direct bond.

As the polymerizable monomer, a compound represented by Formula (Z-4) or (Z-5) can also be used.

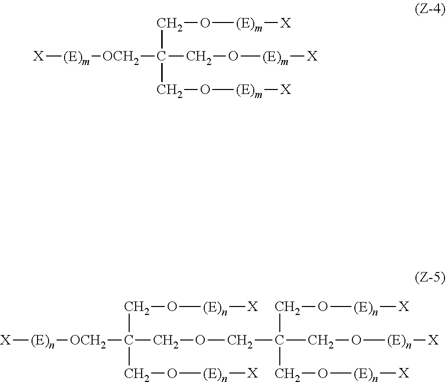

In Formulae (Z-4) and (Z-5), E's each independently represent —((CH₂)_{y}CH₂O)— or —((CH₂)_{y}CH(CH₃)O)—, y's each independently represent an integer of 0 to 10, and X's each independently represent a (meth)acryloyl group, a hydrogen atom, or a carboxyl group. In Formula (Z-4), the total number of (meth)acryloyl groups is 3 or 4, m's each independently represent an integer of 0 to 10, and the sum of m's is an integer of 0 to 40. In Formula (Z-5), the total number of (meth)acryloyl groups is 5 or 6, n's each independently represent an integer of 0 to 10, and the sum of n's is an integer of 0 to 60.

In Formula (Z-4), n represents preferably an integer of 0 to 6 and more preferably an integer of 0 to 4. In addition, the sum of m's is preferably an integer of 2 to 40, more preferably an integer of 2 to 16, and still more preferably an integer of 4 to 8.

In Formula (Z-5), n represents preferably an integer of 0 to 6 and more preferably an integer of 0 to 4. In addition, the sum of n's is preferably an integer of 3 to 60, more preferably an integer of 3 to 24. and still more preferably an integer of 6 to 12.

In addition, it is preferable that, in —((CH₂)_{y}CH₂O)— or —((CH₂)_{y}CH(CH₃)O)— of Formula (Z-4) or (Z-5), a terminal thereof on an oxygen atom side is bonded to X.

(Compound having Cyclic Ether Group)

The photosensitive coloring composition according to the embodiment of the present invention may include a compound having a cyclic ether group as the curable compound. Examples of the cyclic ether group include an epoxy group and an oxetanyl group. It is also preferable that the compound having a cyclic ether group is a compound having an epoxy group. Examples of the compound having an epoxy group include a compound having one or more epoxy groups in one molecule. In particular, a compound having two or more epoxy groups in one molecule is preferable. The number of epoxy groups in one molecule is preferably 1 to 100. The upper limit of the number of epoxy groups is, for example, 10 or less or 5 or less. The lower limit of the number of epoxy groups is preferably 2 or more. As the compound having an epoxy group, compounds described in paragraphs “0034” to “0036” of JP2013-011869A, paragraphs “0147” to “0156” of JP2014-043556A, and paragraphs “0085” to “0092” of JP2014-089408A can also be used. The contents of this specification are incorporated herein by reference.

The compound having an epoxy group may be a low molecular weight compound (for example, molecular weight: lower than 2000 or lower than 1000) or a high molecular weight compound (macromolecule; for example, molecular weight: 1000 or higher, and in the case of a polymer, weight-average molecular weight: 1000 or higher). The weight-average molecular weight of the compound having an epoxy group is preferably 200 to 100000 and more preferably 500 to 50000. The upper limit of the weight-average molecular weight is preferably 10000 or lower, more preferably 5000 or lower, and still more preferably 3000 or lower.

In a case where the compound having an epoxy group is a low molecular weight compound, the compound having an epoxy group is, for example, a compound represented by the following Formula (EP1).

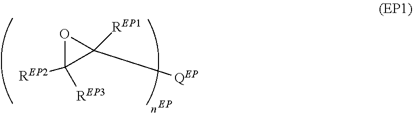

In Formula (EP1), R^{EP1} to R^{EP3} each independently represent a hydrogen atom, a halogen atom, or an alkyl group, live alkyl group may have a cyclic structure or may have a substituent. In addition, R^{EP1} and R^{EP2}, or R^{EP2} and R^{EP3} may be bonded to each other to form a ring structure. Q^{EP} represents a single bond or a n^{EP}-valent organic group. R^{EP1} to R^{EP3} may be bonded to Q^{EP} to form a ring structure. represents an integer of 2 or more, preferably 2 to 10, and more preferably 2 to 6. In a case where Q^{EP} represents a single bond, n^{EP} represents 2. The details of R^{EP1} to and Q^{EP} can be found in paragraphs “0087” and “0088” of JP2014-089408A, the content of which is incorporated herein by reference. Specific examples of the compound represented by Formula (EP1) include a compound described in paragraph “0090” of JP2014-089408A and a compound described in paragraph “0151” of JP2010-054632A, the contents of which are incorporated herein by reference.

Examples of the commercially available product include ADEKA GLYCILOL series manufactured by Adeka Corporation (for example, ADEKA GLYCILOL ED-505) and EPOLEAD series manufactured by Daicel Corporation (for example, EPOLEAD GT401).

As the compound having an epoxy group, an epoxy resin can be preferably used. Examples of the epoxy resin include an epoxy resin which is a glycidyl-etherified product of a phenol compound, an epoxy resin which is a glycidyl-etherified product of various novolac resins, an alicyclic epoxy resin, an aliphatic epoxy resin, a heterocyclic epoxy resin, a glycidyl ester epoxy resin, a glycidyl amine epoxy resin, an epoxy resin which is a glycidylated product of a halogenated phenol, a condensate of a silicon compound having an epoxy group and another silicon compound, and a copolymer of a polymerizable unsaturated compound having an epoxy group and another polymerizable unsaturated compound. The epoxy equivalent of the epoxy resin is preferably 310 to 3300 g/eq, more preferably 310 to 1700 g/eq, and still more preferably 310 to 1000 g/eq.

As the epoxy resin, a commercially available product can also be used. Examples of the commercially available product include EHPE 3150 (manufactured by Daicel Corporation), EPICLON N-695 (manufactured by DIC Corporation), and MARPROOF G-0150M, G-0105SA, G-0130SP, G-0250SP, G-1005S, G-1005SA, G-1010S, G-2050M, G-01100, or G-01758 (manufactured by NOF Corporation, an epoxy group containing polymer).

(Resin)

The photosensitive coloring composition may include a resin as the curable compound. The resin is mixed, for example, in order to disperse the pigment and the like in the composition or to be used as a binder. The resin which is mainly used to disperse the pigments and the like will also be called a dispersant. However, the above-described uses of the resin are merely exemplary, and the resin can be used for purposes other than the uses.

The weight-average molecular weight (Mw) of the resin is preferably 2,000 to 2,000,000. The upper limit is preferably 1,000,000 or lower and more preferably 500,000 or lower. The lower limit is preferably 3,000 or higher and more preferably 5,000 or higher.

Examples of the resin include a (meth)acrylic resin, an enethiol resin, a polycarbonate resin, a polyether resin, a polyarylate resin, a polysulfone resin, a polyethersulfone resin, a polyphenylene resin, a polyarylene ether phosphine oxide resin, a polyimide resin, a polyamide imide resin, a polyolefin resin, a cyclic olefin resin, a polyester resin, and a styrene resin. Among these resins, one kind may be used alone, or a mixture of two or more kinds may be used. As the cyclic olefin resin, a norbornene resin can be preferably used from the viewpoint of improving heat resistance. Examples of a commercially available product of the norbornene resin include ARTON series (for example, ARTON F4520, manufactured by JSR Corporation). In addition, as the resin, a resin described in Examples of WO2016/088645A can also be used.

In the present invention, it is preferable that a resin having an acid group is used as the resin. In this aspect, a pixel having excellent rectangularity is likely to be formed. Examples of the acid group include a carboxyl group, a phosphate group, a sulfo group, and a phenolic hydroxy group. Among these, a carboxyl group is preferable. The resin having an acid group can be used as, for example, an alkali-soluble resin.

It is preferable that the resin having an acid group further includes a repeating unit having an acid group at a side chain, and it is more preferable that the content of the repeating unit having an acid group at a side chain is preferably 5 to 70 mol % with respect to all the repeating units of the resin. The upper limit of the content of the repeating unit having an acid group at a side chain is preferably 50 mol % or lower and more preferably 30 mol % or lower. The lower limit of the content of the repeating unit having an acid group at a side chain is preferably 10 mol % or higher and more preferably 20 mol % or higher.

As the resin having an acid group, a polymer having a carboxyl group at a side chain is preferable. Specific examples of the resin include an alkali-soluble phenol resin such as a methacrylic acid copolymer, an acrylic acid copolymer, an itaconic acid copolymer, a crotonic acid copolymer, a maleic acid copolymer, a partially esterified maleic acid copolymer, or a novolac resin, an acidic cellulose derivative having a carboxyl group at a side chain thereof, and a resin obtained by adding an acid anhydride to a polymer having a hydroxy group. In particular, a copolymer of (meth)acrylic acid and another monomer which is copolymerizable with the (meth)acrylic acid is preferable as the alkali-soluble resin. Examples of the monomer which is copolymerizable with the (meth)acrylic acid include an alkyl (meth)acrylate, an aryl (meth)acrylate, and a vinyl compound. Examples of the alkyl (meth)acrylate and the aryl (meth)acrylate include methyl (meth)acrylate, ethyl (meth)acrylate, propyl (meth)acrylate, butyl (meth)acrylate, isobutyl (meth)acrylate, pentyl (meth)acrylate, hexyl (meth)acrylate, octyl (meth)acrylate, phenyl (meth)acrylate, benzyl (meth)acrylate, tolyl (meth)acrylate, naphthyl (meth)acrylate, and cyclohexyl (meth)acrylate. Examples of the vinyl compound include styrene, α-methylslyrene, vinyl toluene, glycidyl methacrylate, acrylonitrile, vinyl acetate, N-vinylpyrrolidone, tetrahydrofurfuryl methacrylate, a polystyrene macromonomer, and a polymethyl methacrylate macromonomer. Examples of other monomers include a N-position-substituted maleimide monomer described in JP1998-300922A (JP-H10-300922A) such as N-phenylmaleimide or N-cyclohexylmaleimide. Among these monomers which are copolymerizable with the (meth)acrylic acid, one kind may be used alone, or two or more kinds may be used in combination. The details of the resin having an acid group can be found in paragraphs “0558” to “0571” of JP2012-208494A (corresponding to paragraphs “0685” to “0700” of US2012/0235099A) and paragraphs “0076” to “0099” of JP2012-198408A, the contents of which are incorporated herein by reference. In addition, as the resin having an acid group, a commercially available product may also be used. Examples of the commercially available product include ACRYBASE FF-426 (manufactured by Fujikura Kasei Co., Ltd.).

The acid value of the resin having an acid group is preferably 30 to 200 mgKOH/g. The lower limit is preferably 50 mgKOH/g or higher and more preferably 70 mgKOH/g or higher. The upper limit is preferably 150 mgKOH/g or lower and more preferably 120 mgKOH/g or lower.

In the present invention, it is preferable that a resin having a polymerizable group is used as the resin. In this aspect, a pixel having excellent rectangularity and excellent adhesiveness with the support is likely to be formed. In particular, the above-described effect is significant by using the polymerizable monomer and the resin having a polymerizable group in combination as the curable compound. Examples of the polymerizable group include an ethylenically unsaturated bond group such as a vinyl group, a (meth)allyl group, or a (meth)acryloyl group. Among these, a (meth)acryloyl group is preferable,

The weight-average molecular weight of the resin having a polymerizable group is preferably 5,000 to 20,000. The upper limit is preferably 17,000 or lower and more preferably 14,000 or lower. The lower limit is preferably 7,000 or higher and more preferably 9,000 or higher. In a case where the weight-average molecular weight of the resin having a polymerizable group is in the above-described range, an effect of simultaneously improving developability, filterability, and pattern rectangularity can be expected.

The polymerizable group value of the resin having a polymerizable group is preferably 0.5 to 3 mmol/g. The upper limit is preferably 2.5 mmol/g or lower and more preferably 2 mmol/g or lower. The lower limit is preferably 0.9 mmol/g or higher and more preferably 1.2 mmol/g or higher. The polymerizable group value of the resin refers to a numerical value representing the molar amount of the polymerizable group value per 1 g of the solid content of the resin.

The C═C value of the resin having a polymerizable group is preferably 0.6 to 2.8 mmol/g. The upper limit is preferably 2.3 mmol/g or lower and more preferably 1.8 mmol/g or lower. The lower limit is preferably 1.0 mmol/g or higher and more preferably 1.3 mmol/g or higher. The C═C value of the resin refers to a numerical value representing the molar amount of the ethylenically unsaturated bond group per 1 g of the solid content of the resin. The polymerizable group value of the resin can be calculated from the following expression after extracting a low molecular weight component (a) of the polymerizable group portion from the resin by an alkali treatment and measuring the content of the low molecular weight component (a) by high-performance liquid chromatography (HPLC). In addition, in a case where the polymerizable group portion cannot be extracted from resin by an alkali treatment, a value measured using nuclear magnetic resonance (NMR) is used. The same can be applied to the C═C value of the resin.

Polymerizable Group Value [mmol/g] of Resin=(Content [ppm] of Low Molecular Weight Component (a)/Molecular weight [g/mol] of Low Molecular Weight Component (a))/(Weight [g] of Resin×(Concentration Of Solid Contents [mass %] of Resin/100)×10)

It is preferable that the resin having a polymerizable group further includes a repeating unit having a polymerizable group (preferably an ethylenically unsaturated bond group) at a side chain, and it is more preferable that the content of the repenting unit having a polymerizable group at a side chain is preferably 5 to 80 mol % with respect to all the repeating units of the resin. The upper limit of the content of the repeating unit having a polymerizable group at a side chain is preferably 60 mol % or lower and more preferably 40 mol % or lower. The lower limit of the content of the repeating unit having a polymerizable group at a side chain is preferably 15 mol % or higher and more preferably 25 mol % or higher.

It is also preferable that the resin having a polymerizable group further includes a repeating unit having an acid group at a side chain. In this aspect, a pixel having higher rectangularity is likely to be formed. The content of the repeating unit having an acid group at a side chain is preferably 10 to 60 mol % with respect to all the repeating units of the resin. The upper limit is preferably 40 mol % or lower and more preferably 25 mol % or lower. The lower limit is preferably 10 mol % or higher and more preferably 20 mol % or higher.

It is also preferable that the resin used in the present invention includes a repeating unit derived from monomer components including a compound represented by the following Formula (ED1) and or a compound represented by the following Formula (ED2) (hereinafter, these compounds will also be referred to as “ether dimer”) is also preferable.

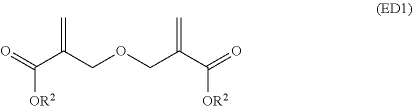

In Formula (ED1), R¹ and R² each independently represent a hydrogen atom or a hydrocarbon group having 1 to 25 carbon atoms which may have a substituent.

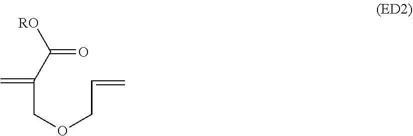

In Formula (ED2), R represents a hydrogen atom or an organic group having 1 to 30 carbon atoms. The details of Formula (ED2) can be found in JP2010-168539A, the content of which is incorporated herein by reference.

Specific examples of the ether dimer can be found in paragraph “0317” of JP2013-029760A. the content of which is incorporated herein by reference.

It is also preferable that the resin used in the present invention includes a repeating unit which is derived from a compound represented by the following Formula (X).

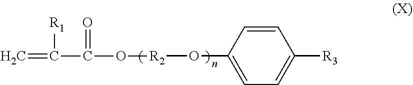

In Formula (X), R₁ represents a hydrogen atom or a methyl group, R₂ represents an alkylene group having 2 to 10 carbon atoms, and R₃ represents a hydrogen atom or an alkyl group having 1 to 20 carbon atoms which may have a benzene ring, n represents an integer of 1 to 15.

Examples of the resin having an acid group and/or a polymerizable group include resins having the following structures. In the following structural formulae, Me represents a methyl group.

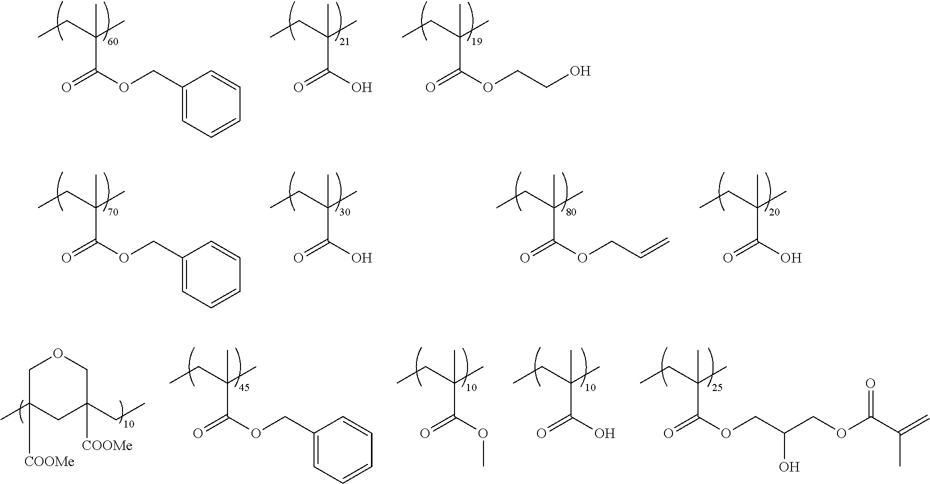

The photosensitive coloring composition according to the embodiment of the present invention may include a resin as a dispersant. Examples of the dispersant include an acidic dispersant (acidic resin) and a basic dispersant (basic resin). Here, the acidic dispersant (acidic resin) refers to a resin in which the amount of an acid group is more than the amount of a basic group. In a case where the sum of the amount of an acid group and the amount of a basic group in the acidic dispersant (acidic resin) is represented by 100 mol %, the amount of the acid group in the acidic resin Is preferably 70 mol % or higher and more preferably substantially 100 mol %. The acid group in the acidic dispersant (acidic resin) is preferably a carboxyl group. An acid value of the acidic dispersant (acidic resin) is preferably 40 to 105 mgKOH/g, more preferably 50 to 105 mgKOH/g, and still more preferably 60 to 105 mgKOH/g. In addition, the basic dispersant (basic resin) refers to a resin in which the amount of a basic group Is more than the amount of an acid group. In a case where the sum of the amount of an acid group and live amount of a basic group in the basic dispersant (basic resin) is represented by 100 mol %, the amount of the basic group in the basic resin is preferably higher than 50 mol %. The basic group in the basic dispersant is preferably an amino group.

It is preferable that the resin A used as the dispersant further includes a repeating unit having an acid group. By the resin, which is used as the dispersant, including the repeating unit having an acid group, in a case where a pixel is formed using a photolithography method, the amount of residues formed in an underlayer of a pixel can be reduced.

It is preferable that the resin used as the dispersant is a graft copolymer. Since the graft copolymer has affinity to the solvent due to the graft chain, the pigment dispersibility and the dispersion stability over time are excellent. The details of the graft copolymer can be found in the description of paragraphs “0025” to “0094” of JP2012-255128A, the content of which is incorporated herein by reference. In addition, specific examples of the graft copolymer include the following resins. The following resin may also be a resin having an acid group (alkali-soluble resin). In addition, other examples of the graft copolymer include resins described in paragraphs “0072” to “0094” of JP2012-255128A, the content of which is incorporated herein by reference.

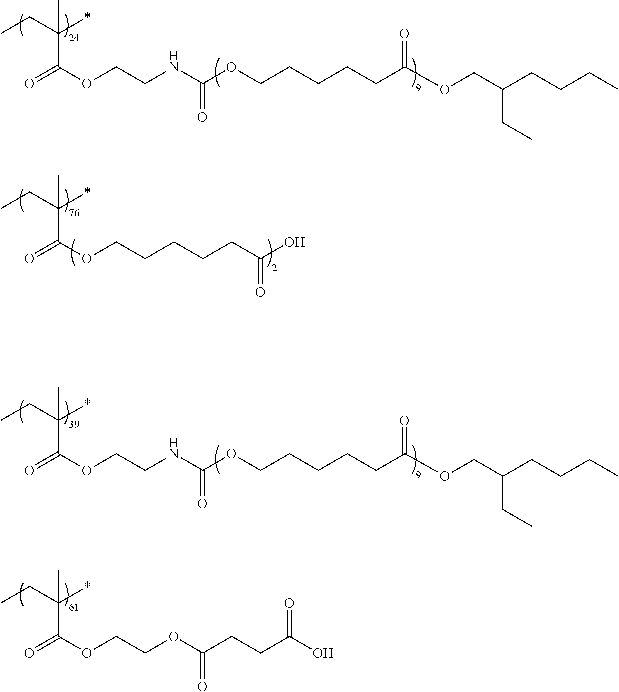

In addition, in the present invention, as the resin (dispersant), an oligoimine dispersant having a nitrogen atom at at least either a main chain or a side chain is also preferably used. As the oligoimine dispersant, a resin, which includes a structural unit having a partial structure X with a functional group (pKa: 14 or lower) and a side chain including a side chain Y having 40 to 10,000 atoms and has a basic nitrogen atom at at least either a main chain or a side chain, is preferable. The basic nitrogen atom is not particularly limited as long as it is a nitrogen atom exhibiting basicity. The oligoimine dispersant can be found in the description of paragraphs “0102” to “0166” of JP2012-255128A, the content of which is incorporated herein by reference. As the oligoimine dispersant, a resin having the following structure or a resin described in paragraphs “0168” to “0174” of JP2012-255128A can be used.

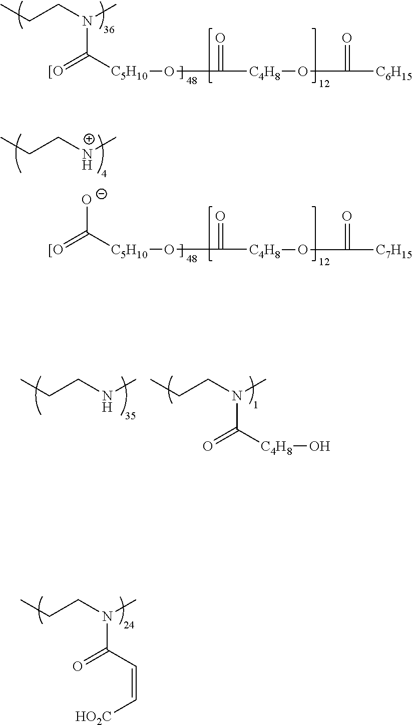

The dispersant is available as a commercially available product, and specific examples thereof include Disperbyk-111 and 161 (manufactured by BYK Chemie). In addition, a pigment dispersant described in paragraphs “0041” to “0130” of JP2014-130338A can also be used, the content of which is incorporated herein by reference. In addition, the resin having an acid group or the like can also be used as a dispersant.

In the photosensitive coloring composition according to the embodiment of the present invention, the content of the curable compound is preferably 5 to 30 mass % with respect to the total solid content of the photosensitive coloring composition. For example, the lower limit is more preferably 7 mass % or higher and still more preferably 9 mass % or higher. For example, the upper limit is more preferably 20 mass % or lower and still more preferably 15 mass % or lower. As the curable compound, one kind may be used alone, or two or more kinds may be used. In a case where two or more curable compounds are used in combination. it is preferable that the total content of the two or more curable compounds is in the above-described range.

It is preferable that the curable compound used in the photosensitive coloring composition according to the embodiment of the present invention includes at least a polymerizable monomer, and it is more preferable that the curable compound used in the photosensitive coloring composition includes at least a resin and a polymerizable monomer. In this aspect, a film having excellent rectangularity and excellent adhesiveness with the support is likely to be formed. In addition, it is preferable that the curable compound includes a resin having an acid group, and it is more preferable that the curable compound includes a resin having a polymerizable group and an acid group.

The content of the polymerizable monomer is preferably 6 to 28 mass % with respect to the total solid content of the photosensitive coloring composition. For example, the lower limit is more preferably 8 mass % or higher and still more preferably 10 mass % or higher. For example, the upper limit is more preferably 18 mass % or lower and still more preferably 13 mass % or lower.

The content of the resin is preferably 5 to 50 mass % with respect to the total solid content of the photosensitive coloring composition. For example, the lower limit is more preferably 10 mass % or higher and still more preferably 15 mass % or higher For example, the upper limit is more preferably 40 mass % or lower and still more preferably 30 mass % or lower. In addition, the content of the resin having on acid group is preferably 7 to 45 mass % with respect to the total solid content of the photosensitive coloring composition. For example, the lower limit is more preferably 12 mass % or higher and still more preferably 17 mass % or higher. For example, the upper limit is more preferably 35 mass % or lower and still more preferably 25 mass % or lower. In addition, the content of the resin having a polymerizable group is preferably 8 to 42 mass % with respect to the total solid content of the photosensitive coloring composition. For example, the lower limit is more preferably 14 mass % or higher and still more preferably 19 mass % or higher. For example, the upper limit is more preferably 32 mass % or lower and still more preferably 22 mass % or lower.

The total content of the polymerizable monomer and the resin is preferably 20 to 80 mass % with respect to the total solid content of the photosensitive coloring composition. For example, the lower limit is more preferably 25 mass % or higher and still more preferably 30 mass % or higher. For example, the upper limit is more preferably 60 mass % or lower and still more preferably 40 mass % or lower. In addition, the content of the polymerizable monomer is preferably 10 to 500 parts by mass with respect to the 100 parts by mass of the resin. The lower limit is preferably 30 pans by mass or more and more preferably 50 parts by mass or more. The upper limit is preferably 300 parts by mass or less and more preferably 100 parts by mass or less. In a case where the mass ratio is in the above-described range, a pixel having higher rectangularity can be formed.

The total content of the polymerizable monomer and the resin having an acid group is preferably 15 to 75 mass % with respect to the total solid content of the photosensitive coloring composition. For example, the lower limit is more preferably 23 mass % or higher and still more preferably 28 mass % or higher. For example, the upper limit Is more preferably 55 mass % or lower and still more preferably 35 mass % or lower. In addition, the content of the polymerizable monomer is preferably 5 to 400 parts by mass with respect to the 100 parts by mass of the resin having an acid group. The lower limit is preferably 20 parts by mass or more and more preferably 40 parts by mass or more. The upper limit is preferably 200 parts by mass or less and more preferably 80 parts by mass or less. In a case where the mass ratio is in the above-described range, a pixel having higher rectangularity can be formal.

It Is preferable that the curable compound used in the photosensitive coloring composition according to the embodiment of the present invention includes a compound having a cyclic ether group. In this aspect, a film having excellent adhesiveness with the support is likely to be formed. The content of the compound having a cyclic ether group is preferably 0.5 to 10 mass % with respect to the total solid content of the photosensitive coloring composition. For example, live lower limit is more preferably 1 mass % or higher and still more preferably 1.5 mass % or higher. For example, the upper limit is more preferably 5 mass % or lower and still more preferably 3 mass % or lower. In addition, the content of the compound having a cyclic ether group is preferably 5 to 50 parts by mass with respect to 100 parts by mass of the polymerizable monomer. The lower limit is preferably 8 parts by mass and more preferably 12 parts by mass. The upper limit Is preferably 30 parts by mass or less and more preferably 20 parts by mass or less. In a case where the mass ratio is in the above-described range, a pixel having higher rectangularity and higher adhesiveness with the support can be formed.

«Photopolymerization Initiator»

It is preferable that the photosensitive coloring composition according to the embodiment of the present invention includes a photopolymerization initiator. It is preferable that the photopolymerization initiator is a compound that reacts with light having a wavelength of 300 nm or shorter to generate a radical.

It is also preferable that the photopolymerization initiator used in the present invention is a compound having a quantum yield of 15% or higher with respect to light having a wavelength of 265 nm. In this specification, the quantum yield of the photopolymerization initiator refers to a value obtained by dividing the number of decomposed molecules by the number of absorbed photons. Regarding the number of absorbed photons, the number of irradiated photons is obtained from an exposure time using a KrF ray approximating light source (wavelength: 265 nm, intensity: 3 mW), an average absorbance at 265 nm before and after exposure is converted into a transmittance, and the number of irradiated photons is multiplied by (1-transmittance) to obtain the number of absorbed photons. Regarding the number of decomposed molecules, a decomposition rate of the photopolymerization initiator is obtained from the absorbance of the photopolymerization initiator after exposure, and the decomposition rate is multiplied by live number of molecules present in the film to obtain the number of decomposed molecules. Examples of the compound having a quantum yield of 15% or higher with respect to light having a wavelength of 265 nm include IRGACURE-OXE01, OXE02, and OXE03 (all of which are manufactured by BASF SE).

It is preferable that the photopolymerization initiator used in the present invention includes at least one compound selected from an alkylphenone compound, an acylphosphine compound, a benzophenone compound, a thioxanthone compound, a triazine compound, a pinacol compound, or an oxime compound, and it is more preferable that the photopolymerization initiator includes an oxime compound.

Examples of the alkylphenone compound include a benzyldimethylketal compound, an α-hydroxyalkylphenone compound, and an α-aminoalkylphenone compound.

Examples of the benzyldimethylketal compound include 2,2-dimedioxy-2-phenylacetophenone. Examples of a commercially available product include IRGACURE-651 (manufactured by BASF SE).

Examples of the α-hydroxyalkylphenone compound include a compound represented by the following Formula (V-I).

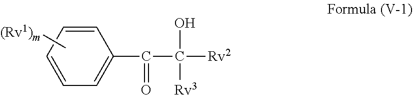

In the formula, Rv¹ represents a substituent, Rv² and Rv³ each independently represent a hydrogen atom or a substituent, Rv² and Rv⁵ bonded to each other to form a ring, and m represents an integer of 0 to 4.

Examples of the substituent represented by RV¹ include an alkyl group having 1 to 10 carbon atoms, an alkoxy group having 1 to 10 carbon atoms, and an aralkyl group having 7 to 20 carbon atoms. The alkyl group and the alkoxy group are preferably linear or branched and more preferably linear. The alkyl group, the alkoxy group, and the aralkyl group represented by Rv¹ may be unsubstituted or may have a substituent. Examples of the substituent include a hydroxy group.

Rv² and Rv³ each independently represent a hydrogen atom or a substituent. As the substituent, an alkyl group having 1 to 10 carbon atoms or an aryl group having 6 to 20 carbon atoms is preferable. In addition, Rv² and Rv³ may be bonded to each other to form a ring (preferably a ring having 4 to 8 carbon atoms and more preferably an aliphatic ring having 4 to 8 carbon atoms). The alkyl group is preferably linear or branched and more preferably linear.

Specific examples of the α-hydroxyalkylphenone compound include 1-hydroxy-cyclolhexyl-phenyl-ketone, 2-hydroxy-2-methyl-1-phenyl-propane-1-one, 1-[4-(2-hydroxyethoxy)-phenyl]-2-hydroxy-2-methyl-1-propane-1-one, and 2-hydroxy-1-{4-[4-(2-hydroxy-2-methyl-propionyl)-benzyl]phenyl}-2-methyl-propane-1-one. Examples of a commercially available product of the α-hydroxyalkylphenone compound include IRGACURE-184, DAROCUR-1173, IRGACURE-500, IRGACURE-2959, and IRGACURE-127 (all of which are manufactured by BASE SE).

Examples of the α-aminoalkylphenone compound include a compound represented by the following Formula (V-2).

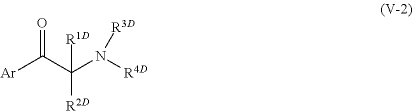

In the formula, Ar represents a phenyl group which is substituted with —SR¹³ or —N(R^{7E})(R^{8E}), and R¹³ represents a hydrogen atom or an alkyl group having 1 to 12 carbon atoms.

R^{1D} and R^{2D} each independently represent an alkyl group having 1 to 8 carbon atoms. R^{1D} and R^{2D} may be bonded to each other to form a ring.

The alkyl group represented by R^{1D} and R^{2D} may be linear, branched, or cyclic and is preferably linear or branched.

The alkyl group represented by R^{1D} and R^{2D} may be unsubstituted or may have a substituent. Examples of the substituent include an aryl group, a heterocyclic group, a nitro group, a cyano group, a halogen atom, —OR^{Y1}, —SR^{Y1}, —COR^{Y1}, —COOR^{Y1}, —OCOR^{Y1}, —NR^{Y1}R^{Y2}, —NHCOR^{Y1}, —CONR^{Y1}R^{Y2}, —NHCONR^{Y1}R^{Y2}, —NHCOOR^{Y1}, —SO₂R^{Y1}, —SO₂OR^{Y1}, and —NHSO₂R^{Y1}. R^{Y1} and R^{Y2} each independently represent a hydrogen atom, an alkyl group, an aryl group, or a heterocyclic group.

Examples of the halogen atom include a fluorine atom, a chlorine atom, a bromine atom, and an iodine atom.

The number of carbon atoms in the alkyl group represented by R^{Y2} and R^{Y2} is preferably 1 to 20. The alkyl group may be linear, branched, or cyclic and is preferably linear or branched.

The number of carbon atoms in the aryl group as the substituent and the aryl group represented by R^{Y1} and R^{Y2} is preferably 6 to 20, more preferably 6 to 15, and still more preferably 6 to 10. The aryl group may be a monocyclic or fused ring.

It is preferable that the heterocyclic group represented by R^{Y1} and R^{Y2} is a 5- or 6-membered ring. The heterocyclic group may be a monocyclic or fused ring. The number of carbon atoms constituting the heterocyclic group is preferably 3 to 30, more preferably 3 to 18, and still more preferably 3 to 12. The number of heteroatoms constituting the heterocyclic group is preferably 1 to 3. It is preferable that the heteroatoms constituting the heterocyclic group are a nitrogen atom, an oxygen atom, or a sulfur atom.

R^{3D} and R^{4D} each independently represent a hydrogen atom or an alkyl group having 1 to 12 carbon atoms. R^{3D} and R^{4D} may be bonded to each other to form a ring. In a case where R^{3D} and R^{4D} are bonded to each other to form a ring, R^{3D} and R^{4D} may be bonded directly to form a ring or may be bonded through —CO—, —O—, or —NH— to form a ring. Examples of the ring which is formed by R^{3D} and R^{4D} being bonded through —O— include a morpholine ring.

R^{7E} and R^{8E} each independently represent a hydrogen atom or an alkyl group having 1 to 12 carbon atoms. R^{7E} and R^{8E} may be bonded to each other to form a ring. In a case where R^{7E} and R^{8E} are bonded to each other to form a ring, R^{7E} and R^{8E} may be bonded directly to form a ring or may be bonded through —CO—, —O—, or —NH— to form a ring. Examples of the ring which is formed by R^{7E} and R^{8E} being bonded through —O— include a morpholine ring.

Specific examples of the α-aminoalkylphenone compound include 2-methyl-1-(4-methylthiophenyl)-2-morpholinopropan-1-one, 2-benzyl-2-dimethylamino-1-(4-morpholinophenyl)-1-butanone, and 2-dimethylamino-2-[(4-methylphenyl)methyl]-1-[4-(4-morpholinyl)phenyl]-1-butanone. Examples of a commercially available product of the α-aminoalkylphenone compound include IRGACURE-907, IRGACURE-369, and IRGACURE-379 (all of which are manufactured by BASF SE).

Examples of the acylphosphine compound include 2,4,6-trimethylbenzoyldiphenyl-phosphine oxide and bis(2,4,6-trimethylbenzoyl)-phenylphosphine oxide. Examples of a commercially available product of the acylphosphine compound include IRGACURE-819 and IRGACURE-TPO (all of which are manufactured by BASF SE).

Examples of the benzophenone compound include benzophenone, methyl o-benzoylbenzoate, 4-phenylbenzophenone, 4-benzoyl-4′-methyldiphenyl sulfide, 3,3′,4,4′-tetra(t-butyl peroxy carbonyl)benzophenone, and 2,4,6′-trimethyl benzophenone.

Examples of the thioxanthone compound include 2-isopropylthioxanthone, 4-isopropylthioxanthone, 2,4-diethylthioxanthone, 2,4-dichlorothioxanthone, and 1-chloro-4-propoxythioxanthone.

Examples of the triazine compound include 2,4-his(trichloromethyl)-6-(4-methoxyphenyl)-1,3,5-triazine, 2,4-bis(trichloromethyl)-6-(4-methoxynaphthyl)-1,3,5-triazine, 2,4-bis(trichloromethyl)-6-piperonyl-1,3,5-triazine, 2,4-bis(trichloromethyl)-6-(4-methoxyscrew)-1,3,5-triazine, 2,4-bis(trichIoromethyl)-6-[2-(5-methylfuran-2-yl)ethenyl]-1,3,5-triazine, 2,4-bis(trichloromethyl)-6-[2-(furan-2-yl)ethenyl]-1,3,5-triazine. 2,4-bis(trichloromethyl)-6-[2-(4-diethylamino-2-methyl phenyl)ethenyl]-1,3,5-triazine, and 2,4-bis(trichloromethyl)-6-[2-(3,4-dimethoxyphenyl)ethenyl]-1,3,5-triazine.

It is preferable that the pinacol compound is a benzopinacol compound. Specific examples of the pinacol compound include benzopinacol, 1,2-dimethoxy-1,1,2,2-tetraphenylethane, 1,2-diethoxy-1,1,2,2-tetraphenylethane, 1,2-diphenoxy-1,1,2,2-tetraphenylethane, 1,2-dimethoxy-1,1,2,2-tetra(4-methylphenyl)ethane, 1,2-diphenoxy-1,1,2,2-tetra(4-methoxyphenyl)ethane, 1,2-bis(trimethylsilloxy)-1,1,2,2-tetraphenylethane, 1,2-bis(triethylsilloxy)-1,1,2,2-tetraphenylethane, 1,2-bis(t-butyldimethylsilloxy)-1,1,2,2-tetraphenylethane, 1-hydroxy-2-trimethylsilloxy-1,1,2,2-tetraphenylethane, 1-hydroxy-2-triethylsilloxy-1,1,2,2-tetraphenylethane, and 1-hydroxy-2-t-butyldimethylsilloxy-1,1,2,2-tetraphenylethane. In addition, the details of the pinacol compound can be found in JP2014-521772A and JP2014-523939A, the contents of which are incorporated herein by reference.

The details of the oxime compound can be found in paragraphs “0212” to “0236” of WO2016/190162A. the content of which is incorporated herein by reference. In addition, as the oxime compound, a compound described in JP2001-233842A, a compound described in JP2000-080068A, a compound described in JP2006-342166A, or a compound described in JP2016-021012A can be used. Examples of the oxime compound which can be preferably used in the present invention include 3-benzoyloxyiminobutane-2-one, 3-acetoxyiminobutane-2-one, 3-propionyloxyirainobutane-2-one, 2-acetoxyiminopentane-3-one, 2-acctoxyimino-1-phenylpropane-1-one, 2-benzoyloxyimino-1-phenylpropane-1-one, 3-(4-toluene sulfonyloxy)iminobutane-2-one, and 2-ethoxycarbonyloxyimino-1-phenylpropane-1-one. In addition, examples of the oxime compound include a compound described in J.C.S. Perkin II (1979), pp. 1653-1660, J.C.S. Perkin II (1979), pp. 156-162 and Journal of Photopolymer Science and Technology (1995), pp. 202-232, JP2000-066385A, JP2000-080068A, JP2004-534797A, or JP2006-342166A. Examples of a commercially available product of the oxime compound include IRGACURE-OXE01, IRGACURE-OXE02, IRGACURE-OXE03, or IRGACURE-OXE04 (all of which are manufactured by BASF SE), TR-PBG-304 (manufactured by Changzhou Tronly New Electronic Materials Co., Ltd.), and ADEKA OPTOMER N-1919 (manufactured by Adeka Corporation, a photopolymerization initiator 2 described in JP2012-014052A). As the oxime compound, a compound having no colorability or a compound having high transparency that is not likely to discolor other components can also be preferably used. Examples of a commercially available product of the oxime compound include ADEKA ARKLS NCI-730, NCI-831, and NCI-930 (all of which are manufactured by Adeka Corporation).

In the present invention, an oxime compound having a fluorene ring can also be used as the photopolymerization initiator. Specific examples of the oxime compound having a fluorene ring include a compound described in JP2014-137466A. The content of this specification is incorporated herein by reference.

In the present invention, an oxime compound having a fluorine atom can also be used as the photopolymerization initiator. Specific examples of the oxime compound having a fluorine atom include a compound described in JP2010-262028A, Compound 24 and 36 to 40 described in JP2014-500852A, and Compound (C-3) described in JP2013-164471A. The content of this specification is incorporated herein by reference.

In the present invention, as the photopolymerization initiator, an oxime compound having a nitro group can be used. It is preferable that the oxime compound having a nitro group is a dimer. Specific examples of the oxime compound having a nitro group include a compound described in paragraphs “0031” to “0047” of JP2013-114249A and paragraphs “0008” to “0012” and “0070” to “0079” of JP2014-137466A, a compound described in paragraphs “0007” to 0025” of JP4223071B, and AREKA ARKLS NCI-831 (manufactured by Adeka Corporation).

In the present invention, as the photopolymerization initiator, an oxime compound having a benzofuran skeleton can also be used. Specific examples include OE-01 to OE-75 described in WO2015/036910A.

Hereinafter, specific examples of the oxime compound which are preferably used in the present invention are shown below, but the present invention is not limited thereto.

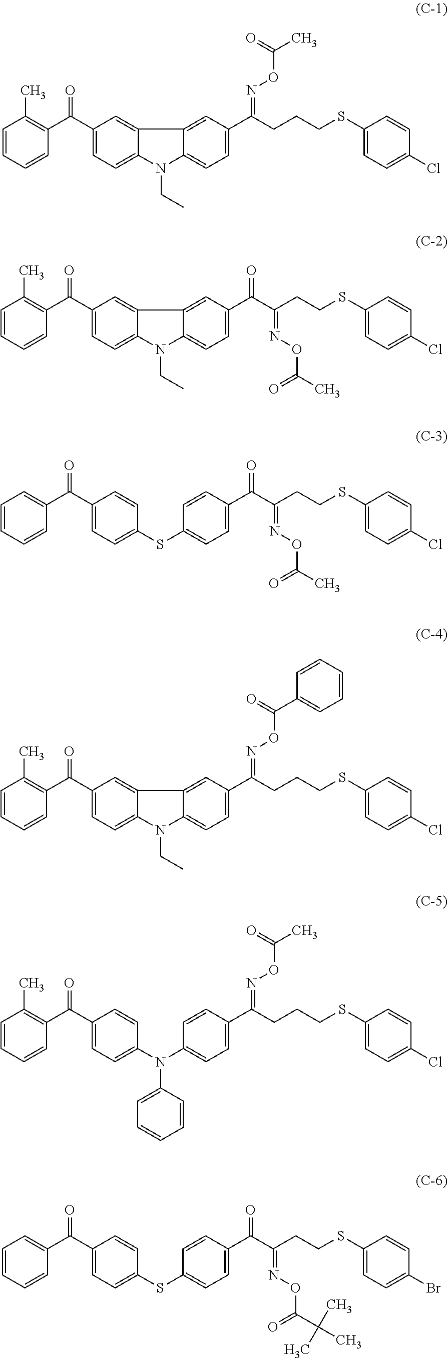 [SMILES: CCn1c2ccc(C(=O)c3ccccc3C)cc2c2cc(/C(CCCSc3ccc(Cl)cc3)=N/OC(C)=O)ccc21 ; CCn1c2ccc(C(=O)/C(CCSc3ccc(Cl)cc3)=N/OC(C)=O)cc2c2cc(C(=O)c3ccccc3C)ccc21 ; CC(=O)O/N=C(\CCSc1ccc(Cl)cc1)C(=O)c1ccc(Sc2ccc(C(=O)c3ccccc3)cc2)cc1 ; CCn1c2ccc(C(=O)c3ccccc3C)cc2c2cc(/C(CCCSc3ccc(Cl)cc3)=N/OC(=O)c3ccccc3)ccc21 ; CC(=O)O/N=C(\CCCSc1ccc(Cl)cc1)c1ccc(N(c2ccccc2)c2ccc(C(=O)c3ccccc3C)cc2)cc1 ; CC(C)(C)C(=O)O/N=C(\CCSc1ccc(Br)cc1)C(=O)c1ccc(Sc2ccc(C(=O)c3ccccc3)cc2)cc1]

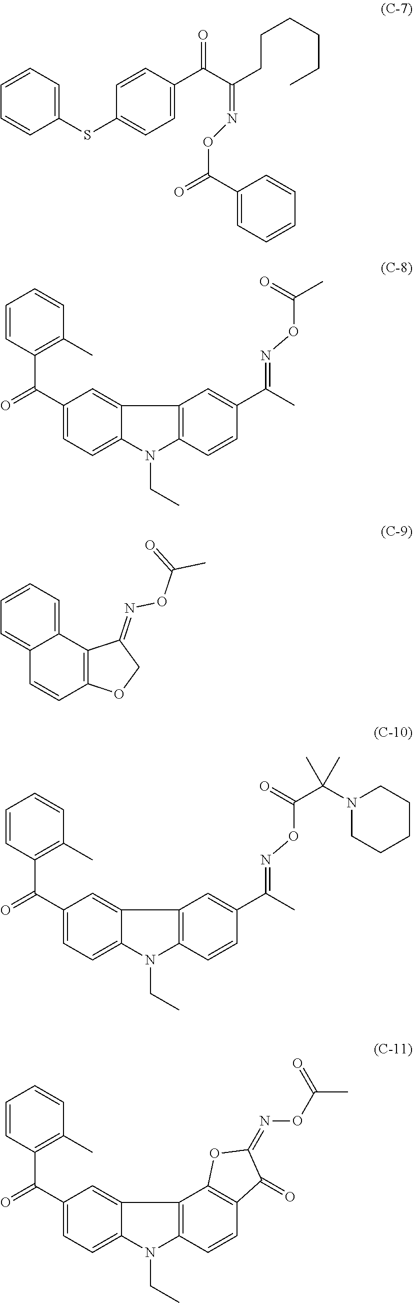

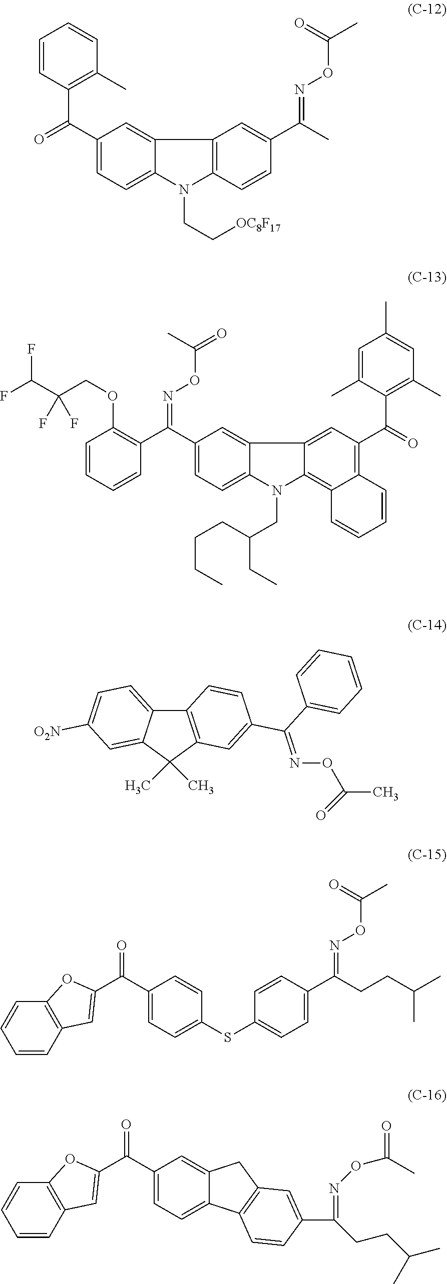

The content of the photopolymerization initiator is preferably 0.1 to 30 mass % with respect to the total solid content of the photosensitive coloring composition. For example, the lower limit is preferably 0.5 mass % or higher and more preferably 1 mass % or higher. For example, the upper limit is more preferably 25 mass % or lower and still more preferably 20 mass % or lower. As the photopolymerization initiator, one kind may be used alone, or two or more kinds may be used in combination. In a case where two or more photopolymerization initiators are used in combination, it is preferable that the total content of the two or more photopolymerization initiators is in the above-described range.

«Silane Coupling Agent»

The photosensitive coloring composition according to the embodiment of the present invention may include a silane coupling agent. In this aspect, the adhesiveness of the obtained film with the support can be further improved. In the present invention, the silane coupling agent refers to a silane compound having a functional group other than a hydrolyzable group. In addition, the hydrolyzable group refers to a substituent directly linked to a silicon atom and capable of forming a siloxane bond due to at least one of a hydrolysis reaction or a condensation reaction. Examples of the hydrolyzable group include a halogen atom, an alkoxy group, and an acyloxy group. Among these, an alkoxy group is preferable. That is, it is preferable that the silane coupling agent is a compound having an alkoxysilyl group. Examples of the functional group other than a hydrolyzable group include a vinyl group, a (meth)allyl group, a (meth)acryloyl group, a mercapto group, an epoxy group, an oxetanyl group, an amino group, an ureido group, a sulfide group, an isocyanate group, and a phenyl group. Among these, an amino group, a (meth)acryloyl group, or an epoxy group Is preferable. Specific examples of the silane coupling agent include a compound having the following structure. In addition, specific examples of the silane coupling agent include a compound described in paragraphs “0018” to “0036” of JP2009-288703A and a compound described in paragraphs “0056” to “0066” of JP2009-242604A, the contents of which are incorporated herein by reference.

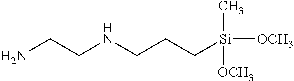

The content of the silane coupling agent is preferably 0.1 to 5 mass % with respect to the total solid content of the photosensitive coloring composition. The upper limit is preferably 3 mass % or lower, and more preferably 2 mass % or lower. The lower limit is preferably 0.5 mass % or higher and more preferably 1 mass % or higher. As the silane coupling agent, one kind may be used alone, or two or more kinds may be used. In a case where two or more silane coupling agents are used in combination, it is preferable that the total content of the two or more silane coupling agents is in the above-described range.

«Pigment Derivative»

The photosensitive coloring composition according to the embodiment of the present invention may further include a pigment derivative. Examples of the pigment derivative include a compound having a structure in which a portion of a pigment is substituted with an acid group, a basic group, a group having a salt structure, or a phthalimidomethyl group. As the pigment derivative, a compound represented by Formula (B1) is preferable.

P—(—L—(X)ₙ)ₘ (B1)

In Formula (B1), P represents a colorant structure, L represents a single bond or a linking group. X represents an acid group, a basic group, a group having a salt structure, or a phthalimidomethyl group, m represents an integer of 1 or more, n represents an integer of 1 or more, in a ease where m represents 2 or more, a plurality of L's and a plurality of X's may be different from each other, and in a case where n represents 2 or more, a plurality of X's may be different from each other.

The colorant structure represented by P is preferably at least one selected from a pyrrolopyrrole colorant structure, a diketo pyrrolopyrrole colorant structure, a quinacridone colorant structure, an anthraquinone colorant structure, a dianthraquinone colorant structure, a benzoisoindole colorant structure, a thiazine indigo colorant structure, an azo colorant structure, a quinophthalone colorant structure, a phthalocyanine colorant structure, a naphthalocyanine colorant structure, a dioxazine colorant structure, a perylene colorant structure, a perinone colorant structure, a benzimidazolone colorant structure, a benzothiazole colorant structure, a benzimidazole colorant structure, or a benzoxazole colorant structure, more preferably at least one selected from a pyrrolopyrrole colorant structure, a diketo pyrrolopyrrole colorant structure, a quinacridone colorant structure, or a benzimidazolone colorant structure, and still more preferably a pyrrolopyrrole colorant structure.

Examples of the linking group represented by L include a hydrocarbon group, a heterocyclic group, —NR—, —SO₂—, —S—, —O—, —CO—, and a group of a combination thereof R represents a hydrogen atom, an alkyl group, or an aryl group.

Examples of the acid group represented by X include a carboxyl group, a sulfo group, a carboxylic acid amide group, a sulfonic acid amide group, and an imide acid group. As the carboxylic acid amide group, a group represented by —NHCOR^{X1} is preferable. As the sulfonic acid amide group, a group represented by —NHSO₂R^{X2} is preferable. As the imide acid group, a group represented by —SO₂NHSO₂R^{X3}, —CONHSO₂R^{X4}, —CONHCOR_{X5}, or —SO₂NHCOR^{X6} is preferable. R^{X1} to R^{X6} each independently represent a hydrocarbon group or a heterocyclic group. The hydrocarbon group and the heterocyclic group represented by R^{X1} to R^{X6} may further have a substituent. As the substituent which may be further included, a halogen atom is preferable, and a fluorine atom is more preferable. Examples of the basic group represented by X include an amino group. Examples of the salt structure represented by X include a salt of the acid group or the basic group described above.

Examples of the pigment derivative include compounds having the following structures. In addition, for example, compounds described in JP1981-118462A (JP-S56-118462A), JP1988-264674A (JP-S63-264674A), JP1989-217077A (JP-H1-217077A), JP1991-009961A (JP-H3-009961A), JP1991-026767A (JP-H3-026767A), JP1991-153780A (JP-H3-153780A), JP1991-045662A (JP-H3-045662A), JP1992-285669A (JP-H4-285669A), JP1994-145546A (JP-H6-145546A), JP1994-212088A (JP-H6-212088A), JP1994-240158A (JP-H6-240158A), JP1998-030063A (JP-H10-030063A), JP1998-195326A (JP-H10-195326A), paragraphs “0086” to “0098” of WO2011/024896A, paragraphs “0063” to “0094” of WO2012/I12399A, and paragraph “0082” of WO2017/0382S2A can be used, the content of which is incorporated herein by reference.

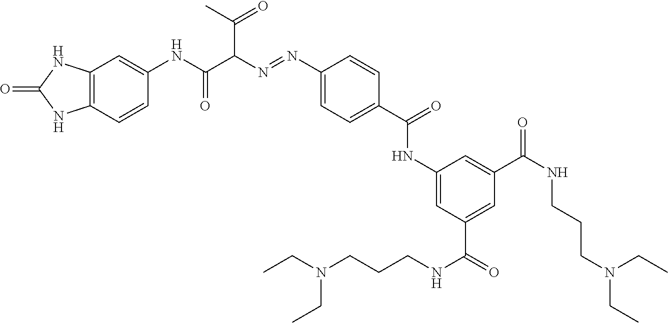 [SMILES: CCN(CC)CCCNC(=O)c1cc(NC(=O)c2ccc(/N=N/C(C(C)=O)C(=O)Nc3ccc4[nH]c(=O)[nH]c4c3)cc2)cc(C(=O)NCCCN(CC)CC)c1]

The content of the pigment derivative is preferably 1 to 50 parts by mass with respect to 100 parts by mass of the pigment. The lower limit value is preferably 3 parts by mass or more and more preferably 5 parts by mass or more. The upper limit value is preferably 40 parts by mass or less and more preferably 30 parts by mass or less. In a case where the content of the pigment derivative is in the above-described range, the pigment dispersibility can be improved, and aggregation of the pigment can be effectively suppressed. As the pigment derivative, one kind may be used alone, or two or more kinds may be used in combination. In a case where two or more pigment derivatives are used in combination, it is preferable that the total content of the two or more pigment derivatives is in the above-described range.

«Solvent»

The photosensitive coloring composition according to the embodiment of the present invention may include a solvent. Examples of the solvent include an organic solvent. Basically, the solvent is not particularly limited as long as it satisfies the solubility of the respective components and the application properties of the composition. Examples of the organic solvent include esters, ethers, ketones, and aromatic hydrocarbons. The details of the organic solvent can be found in paragraph “0223” of WO2015/166779A, the content of which is incorporated herein by reference. In addition, an ester solvent in which a cyclic alkyl group is substituted or a ketone solvent in which a cyclic alkyl group is substituted can also be preferably used. Specific examples of the organic solvent include dichloromethane, methyl 3-ethoxypropionate, ethyl 3-ethoxypropionate, ethyl cellosolve acetate, ethyl lactate, diethylene glycol dimethyl ether, butyl acetate, methyl 3-methoxypropionate, 2-heptanone, cyclohexanone, cyclohexyl acetate, cyclopentanone, ethyl carbitol acetate, butyl carbitol acetate, propylene glycol monomethyl ether, and propylene glycol monomethyl ether acetate. In the present invention, as the organic solvent, one kind may be used alone, or two or more kinds may be used in combination. In addition, 3-methoxy-N,N-dimethylpropanamide or 3-butoxy-N,N-dimethylpropanamide is also preferable from the viewpoint of improving solubility. In this case, it may be preferable that the content of the aromatic hydrocarbon (for example, benzene, toluene, xylene, or ethylbenzene) as the solvent is low (for example, 50 mass parts per million (ppm) or lower, 10 mass ppm or lower, or 1 mass ppm or lower with respect to the total mass of the organic solvent) in consideration of environmental aspects and the like.

In the present invention, a solvent having a low metal content is preferably used. For example, the metal content in the solvent is preferably 10 mass parts per billion (ppb) or lower. Optionally, a solvent having a metal content at a mass parts per trillion (ppt) level may be used. For example, such a high-purity solvent is available from Toyo Gosei Co., Ltd. (The Chemical Daily, Nov. 13, 2015).

Examples of a method of removing impurities such as metal from the solvent include distillation (for example, molecular distillation or thin-film distillation) and filtering using a filter, live pore size of a filter used for the filtering is preferably 10 μm or less, more preferably 5 μm or less, and still more preferably 3 μm or less. As a material of the filter, polytetrafluoroethylene, polyethylene, or nylon is preferable.

The solvent may include an isomer (a compound having the same number of atoms and a different structure). In addition, the organic solvent may include only one isomer or a plurality of isomers.

In the present invention, as the organic solvent, an organic solvent containing 0.8 mmol/L or lower of a peroxide is preferable, and an organic solvent containing substantially no peroxide is more preferable.

The content of the solvent is preferably 10 to 95 mass %, more preferably 20 to 90 mass %. and still more preferably 30 to 90 mass % with respect to the total mass of the photosensitive coloring composition. In addition, due to the reasons of an environmental aspect, it may be preferable that the photosensitive coloring composition does not include an aromatic hydrocarbon (for example, benzene, toluene, xylene, or ethylbenzene) as a solvent.

«Polymerization Inhibitor»

The photosensitive coloring composition according to the embodiment of the present invention may include a polymerization inhibitor. Examples of the polymerization inhibitor include hydroquinone, p-methoxyphenol, di-tert-butyl-p-cresol, pyrogallol, tert-butylcatechol, benzoquinone, 4,4′-thiobis(3 -methyl-6-tert-butylphenol), 2,2′-methylenebis(4-methyl-6-t-butylphenol), and N-nitrosophenylhydroxyamine salt (for example, an ammonium salt or a cerium (III) salt). Among these, p-methoxyphenol is preferable. The contort of the polymerization inhibitor is preferably 0.001 to 5 mass % with respect to the total solid content of the photosensitive coloring composition.

«Surfactant»

It is preferable that the photosensitive coloring composition according to the embodiment of the present invention includes a surfactant. As the surfactants, various surfactants such as a fluorine surfactant, a nonionic surfactant, a cationic surfactant, an anionic surfactant, or a silicone surfactant can be used. The details of the surfactant can be found in paragraphs “0238” to “0245” of WO2015/166779A, the content of which is incorporated herein by reference.

In the present invention, it is preferable that the surfactant is a fluorine surfactant. By the photosensitive coloring composition containing a fluorine surfactant, liquid characteristics (in particular, fluidity) are further improved, and liquid saving properties can be further improved. In addition, a film having reduced thickness unevenness can be formed.

The fluorine content in the fluorine surfactant is preferably 3 to 40 mass %, more preferably 5 to 30 mass %, and still more preferably 7 to 25 mass %. The fluorine surfactant in which the fluorine content is in the above-described range is effective from the viewpoints of the uniformity in the thickness of the coating film and liquid saving properties, and the solubility thereof in the composition is also excellent.

Specific examples of the fluorine surfactant include a surfactant described in paragraphs “0060” to “0064” of JP2014-041318A (paragraphs “0060” to “0064” of corresponding WO2014/017669A) and a surfactant described in paragraphs “0117” to “0132” of JP2011-132503A, the contents of which are incorporated herein by reference. Examples of a commercially available product of the fluorine surfactant include: MEGAFACE F171, F172, F173, F176, F177, F141, F142, F143, F144, R30, F437, F475, F479, F482, F554, F780, EXP, and MFS-330 (all of which are manufactured by DIC Corporation); FLUORAD FC430, FC431, and FC171 (all of which are manufactured by Sumitomo 3M Ltd.); SURFLON S-382, SC-101, SC-103, SC-104, SC-105, SC-1068, SC-381, SC-383, S-393, and KJ1-40 (all of which are manufactured by Asahi Glass Co., Ltd.); and POLYFOX PF636, PF656, PF6320, PF6520, and PF7002 (all of which are manufactured by OMNOVA Solutions Inc.).

In addition, as the fluorine surfactant, an acrylic compound having a molecular structure which has a functional group having a fluorine atom and in which the functional group having a fluorine atom is cut and a fluorine atom is volatilized during heat application can also be preferably used. Examples of the fluorine surfactant include MEGAFACE DS series (manufactured by DIC Corporation, The Chemical Daily, Feb. 22, 2016, Nikkei Business Daily, Feb. 23,2016), for example, MEGAFACE DS-21.

In addition, as the fluorine surfactant, a polymer of a fluorine-containing vinyl ether compound having a fluorinated alkyl group or a fluorinated alkylene ether group and a hydrophilic vinyl ether compound is also preferable. The details of this fluorine surfactant can be found in JP2016-216602A, the content of which is incorporated herein by reference.

As the fluorine surfactant, a block polymer can also be used. Examples of the block polymer include a compound described in JP2011-089090A. As the fluorine surfactant, a fluorine-containing polymer compound can be preferably used, the fluorine-containing polymer compound including: a repeating unit derived from a (meth)acrylate compound having a fluorine atom; and a repeating unit derived from a (meth)acrylate compound having 2 or more (preferably 5 or more) alkyleneoxy groups (preferably an ethyleneoxy group and a propyleneoxy group). For example, the following compound can also be used as the fluorine surfactant used in the present invention.

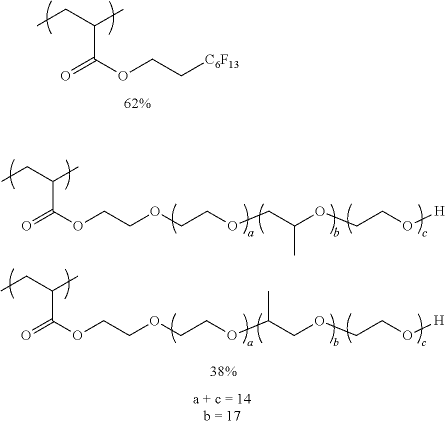

The weight-average molecular weight of the compound is preferably 3,000 to 50,000 and, for example, 14,000. In the compound, “%” representing the proportion of a repeating unit is mol %.

In addition, as the fluorine surfactant, a fluorine-containing polymer having an ethylenically unsaturated bond group at a side chain can also be used. Specific examples include a compound described in paragraphs “0050” to “0090” and paragraphs “0289” to “0295” of JP2010-164965A, for example, MEGAFACE RS-101, RS-102, RS-718K, and RS-72-K manufactured by DIC Corporation. As the fluorine surfactant, a compound described in paragraphs “0015” to “0158” of JP2015-117327A can also be used.

Examples of the nonionic surfactant include glycerol, trimethylolpropane, trimethylolethane, an ethoxylate and a propoxylate thereof (for example, glycerol propoxylate or glycerol ethoxylate), polyoxyethylene lauryl ether, polyoxyethylene stearyl ether, polyoxyethylene oleyl ether, polyoxyethylene octylphenyl ether, polyoxyethylene nonylphenyl ether, polyethylene glycol dilaurate, polyethylene glycol distearate, sorbitan fatty acid esters, PLURONIC L10, L31, L61, L62, 10R5, 17R2, and 25R2 (manufactured by BASF SE), TETRONIC 304, 701, 704, 901, 904, and 150R1 (manufactured by BASF SE)), SOLSPERSE 20000 (manufactured by Lubrication Technology Inc.), NCW-101, NCW-1001, and NCW-1002 (all of which are manufactured by Wako Pure Chemical Industries. Ltd.), PIONIN D-6112, D-6112-W, and D-6315 (all of which are manufactured by Takemoto Oil&Fat Co., Ltd.), and OLFINE E1010, SURFYNOL 104, 400, and 440 (all of which are manufactured by Nissin Chemical Co., Ltd.).

Examples of the silicone surfactant include: TORAY SILICONE DC3PA, TORAY SILICONE SH7PA, TORAY SILICONE DC11PA, TORAY SILICONE SH21PA, TORAY SILICONE SH28PA, TORAY SILICONE SH29PA, TORAY SILICONE SH30PA, and TORAY SILICONE SH8400 (all of which are manufactured by Dow Coming Corporation); TSF-4440, TSF-4300, TSF-4445, TSF-4460, and TSF-4452 (all of which are manufactured by Momentive Performance Materials Inc.); KP-341, KF-6001, and KF-6002 (all of which are manufactured by Shin-Etsu Chemical Co., Ltd.); and BYK307, BYK323, and BYK330 (all of which are manufactured by BYK-Chemie Japan K.K.). In addition, as the silicon surfactant, a compound having the following structure can also be used.

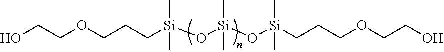

The content of the surfactant is preferably 0.001 mass % to 5.0 mass % and more preferably 0.005 to 3.0 mass % with respect to the total solid content of the photosensitive coloring composition. As the surfactant, one kind may be used alone, or two or more kinds may be used. In a case where two or more surfactants are used in combination, it is preferable that the total content of the two or more surfactants is in the above-described range.

«Ultraviolet Absorber»

The photosensitive coloring composition according to the embodiment of the present invention may include an ultraviolet absorber. As the ultraviolet absorber, for example, a conjugated dione compound, an aminobutadiene compound, a methyldibenzoyl compound, a coumarin compound, a salicylate compound, a benzophenone compound, a benzotriazole compound, an acrylonitrile compound, an azomethine compound, an indole compound, or a triazine compound can be used. The details of the ultraviolet absorber can be found in paragraphs “0052” to “0072” of JP2012-208374A, paragraphs “0317” to “0334” of JP2013-068814A, and paragraphs “0061” to “0080” of JP2016-162946A, the contents of which are incorporated herein by reference. Examples of a commercially available product of the conjugated diene compound include UV-503 (manufactured by Dai to Chemical Co., Ltd.). Specific examples of the indole compound include compounds having the following structures. In addition, as the benzotriazole compound, MYUA series (manufactured by Miyoshi Oil&Fat Co., Ltd.; The Chemical Daily, Feb. 1, 2016) may be used.

In the present invention, as the ultraviolet absorber, compounds represented by Formulae (UV-1) to (UV-3) can also be preferably used.

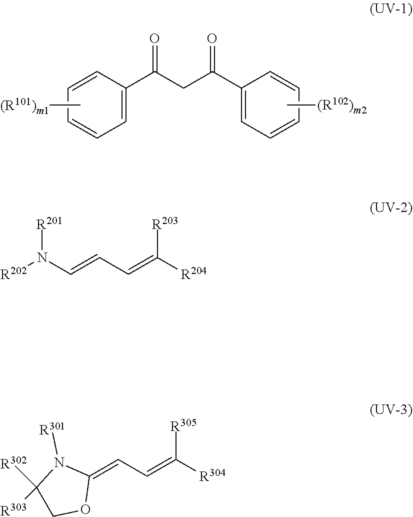

In Formula (UV-1), R¹⁰¹ and R¹⁰² each independently represent a substituent, and m1 and m2 each independently represent 0 to 4. In Formula (UV-2), R²⁰¹ and R²⁰² each independently represent a hydrogen atom or an alkyl group, and R²⁰⁵ and R²⁰⁴ each independently represent a substituent. In Formula (UV-3), R³⁰¹ to R³⁰³ each independently represent a hydrogen atom or an alkyl group, and R³⁰⁴ and R³⁰⁵ each independently represent a substituent.

Specific examples of the compounds represented by Formulae (UV-1) to (UV-3) include the following compounds.

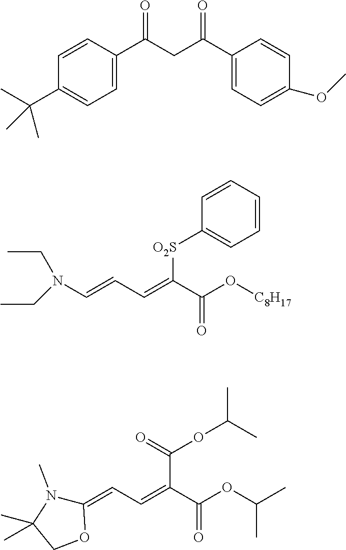

The content of the ultraviolet absorber is preferably 0.01 to 10 mass % and more preferably 0.01 to 5 mass % with respect to the total solid content of the photosensitive coloring composition. In the present invention, as the ultraviolet absorber, one kind may be used alone, or two or more kinds may be used. In a case where two or more ultraviolet absorbers are used in combination, it is preferable that the total content of the two or more ultraviolet absorbers is in the above-described range.

«Antioxidant»

The photosensitive coloring composition according to the embodiment of the present invention may include an antioxidant, Examples of the antioxidant include a phenol compound, a phosphite compound, and a thioether compound. As the phenol compound, any phenol compound which is known as a phenol antioxidant can be used. As the phenol compound, for example, a hindered phenol compound is preferable. A compound having a substituent at a position (ortho position) adjacent to a phenolic hydroxy group is preferable. As the substituent, a substituted or unsubstituted alkyl group having 1 to 22 carbon atoms is preferable. In addition, as the antioxidant, a compound having a phenol group and a phosphite group in the same molecule is also preferable. In addition, as the antioxidant, a phosphorus antioxidant can also be preferably used. Examples of the phosphorus antioxidant include tris[2-[[2,4,8,10-tetrakis(1,1-dimethylethyl)dibenzo[d,f][1,3,2]dioxaphosphepin-6-yl]oxy]ethyl]amine, tris[2-[(4,6,9,11-tetra-tert-butyldibenzo[d,f][1,3,2]dioxaphosphepin-2-yl)oxy]ethyl]amine, and ethyl bis(2,4-di-tert-butyl-6-methylphenyl)phosphite. Examples of the commercially available product of the antioxidant include ADEKA STAB AO-20, ADEKA STAB AO-30, ADEKA STAB AO-40, ADEKA STAB AO-50, ADEKA STAB AO-50F, ADEKA STAB AO-60, ADEKA STAB AO-60G, ADEKA STAB AG-80, and ADEKA STAB AO-330 (all of which are manufactured by Adeka Corporation).

The content of the antioxidant is preferably 0.01 to 20 mass % and more preferably 0.3 to 15 mass % with respect to the mass of the total solid content of the photosensitive coloring composition. As the antioxidant, one kind may be used alone, or two or more kinds may be used in combination. In a case where two or more antioxidants are used in combination, it is preferable that the total content of the two or more antioxidants is in the above-described range.

«Other Components»

Optionally, the photosensitive coloring composition according to the embodiment of the present invention may further include a sensitizer, a curing accelerator, a filler, a thermal curing accelerator, a plasticizer, and other auxiliary agents (for example, conductive particles, a filler, an antifoaming agent, a flame retardant, a leveling agent, a peeling accelerator, an aromatic chemical, a surface tension adjuster, or a chain transfer agent). By the composition appropriately including the components, properties such as film properties can be adjusted. The details of the components can be found in, for example, paragraph “0183” of JP2012-003225A (corresponding to paragraph “0237” of U.S.2013/0034812A) and paragraphs “0101” to “0104” and “0107” to “0109” of JP2008-250074A, the contents of which are incorporated herein by reference. In addition, the photosensitive coloring composition according to the embodiment of the present invention may optionally include a potential antioxidant. The potential antioxidant is a compound in which a portion that functions as the antioxidant is protected by a protective group and this protective group is desorbed by heating the compound at 100° C. to 250° C. or by heating the compound at 80° C. to 200° C. in the presence of an acid/a base catalyst. Examples of the potential antioxidant include a compound described in WO2014/021023A, WO2017/030005A, and JP2017-008219A. Examples of a commercially available product of the potential antioxidant include ADEKA ARKLS GPA-5001 (manufactured by Adeka Corporation).

For example, in a case where a film is formed by coating, the viscosity (23° C.) of the photosensitive coloring composition according to the embodiment of the present invention is preferably 1 to 100 mPa⋅s. The lower limit is more preferably 2 mPa⋅s or higher and still more preferably 3 mPa⋅s or higher. The upper limit is more preferably 50 mPa⋅s or lower, still more preferably 30 mPa⋅s or lower, and still more preferably 15 mPa⋅s or lower.

<Storage Container>

A storage container of the photosensitive coloring composition according to the embodiment of the present invention is not particularly limited, and a well-known storage container can be used. In addition, as the storage container, in order to suppress infiltration of impurities into the raw materials or the composition, a multilayer bottle in which a container inner wall having a six-layer structure is formed of six kinds of resins or a bottle in which a container inner wall having a seven-layer structure is formed of six kinds of resins is preferably used. Examples of the container include a container described in JP2015-123351A.

<Method of Preparing Photosensitive Coloring Composition>

The photosensitive coloring composition according to the embodiment of the present invention can be prepared by mixing the above-described components with each other. During the preparation of the photosensitive coloring composition, all the components may be dissolved or dispersed in a solvent at the same time to prepare the photosensitive coloring composition. Optionally, two or more solutions or dispersions to which the respective components are appropriately added may be prepared, and the solutions or dispersions may be mixed with each other during use (during application) to prepare the photosensitive coloring composition.

In addition, in a case where the photosensitive coloring composition according to the embodiment of the present invention includes particles of a pigment or the like, it is preferable that a process of dispersing the particles is provided. Examples of a mechanical force used for dispersing the panicles in the process of dispersing the particles include compression, squeezing, impact, shearing, and cavitation. Specific examples of the process include a beads mill, a sand mill, a roll mill, a ball mill, a paint shaker, a Microfluidizer, a high-speed impeller, a sand grinder, a flow jet mixer, high-pressure wet atomization, and ultrasonic dispersion. During the pulverization of the particles using a sand mill (beads mill), it is preferable that the process is per formal under conditions for increasing the pulverization efficiency, for example, by using beads having a small size and increasing the filling rate of the beads. In addition, it is preferable that coarse particles are removed by filtering, centrifugal separation, and the like after pulverization. In addition, as the process and the disperser for dispersing the particles, a process and a disperser described in “Complete Works of Dispersion Technology, Johokiko Co., Ltd., Jul. 15, 2005”, “Dispersion Technique focusing on Suspension (Solid/Liquid Dispersion) and Practical Industrial Application, Comprehensive Reference List, Publishing Department of Management Development Center, Oct. 10, 1978”, and paragraph “0022” JP2015-157893 A can be suitably used. In addition, in the process of dispersing the particles, particles may be refined in a salt milling step. A material, a device, process conditions, and the like used in the salt milling step can be found in, for example, JP2015-194521A and JP2012-046629A.

During the preparation of the photosensitive coloring composition according to the embodiment of foe present invention, it is preferable that foe photosensitive coloring composition is filtered through a filter, for example, in order to remove foreign matter or to reduce defects. As the filter, any filter which is used in the related art for filtering or the like can be used without any particular limitation. Examples of a material of the filter include: a fluororesin such as polytetrafluoroethylene (PTFE); a polyamide resin such as nylon (for example, nylon-6 or nylon-6,6); and a polyolefin resin (including a polyolefin resin having a high density and an ultrahigh molecular weight) such as polyethylene or polypropylene (PP). Among these materials, polypropylene (including high-density polypropylene) or nylon is preferable.

The pore size of the filter is suitably about 0.01 to 7.0 μm and is preferably about 0.01 to 3.0 μm and more preferably about 0.05 to 0.5 μm. In a case where the pore size of the filter is in the above-described range, fine foreign matter can be reliably removed. In addition, it is preferable that a fibrous filter material is used. Examples of the fibrous filter material include polypropylene fiber, nylon fiber, and glass fiber. Specific examples include a filter cartridge of SBP type series (for example, SBP008). TPR type series (for example, TPR002 or TPR005), and SHPX type series (for example. SHPX003) all of which are manufactured by Roki Techno Co., Ltd.

In a case where a filter is used, a combination of different filters (for example, a first filter and a second filter) may be used. At this time, the filtering using each of the filters may be performed once, or twice or more.

In addition, a combination of filters having different pore sizes in the above-described range may be used. Here, the pore size of the filter can refer to a nominal value of a manufacturer of the filter. A commercially available filter can be selected from various filters manufactured by Pall Corporation (for example, DFA4201NXEY), Toyo Roshi Kaisha, Ltd., Entegris Japan Co., Ltd. (former Mykrolis Corporation), or Kits Microfilter Corporation. The second filter may be formed of the same material as that of the first filler. In addition, the filtering using the first filter may be performed only on the dispersion, and the filtering using the second filter may be performed on a mixture of the dispersion and other components.

<Method of Manufacturing Optical Filter>

Next, a method of manufacturing the optical filter according to the embodiment of the present invention will be described.

The method of manufacturing an optical filter according to an embodiment of the present invention comprises:
a step (photosensitive coloring composition layer forming step) of forming a photosensitive coloring composition layer having an optical density of 1.6 or higher with respect to light having a wavelength of 248 nm on a support using a photosensitive coloring composition including a coloring material and a curable compound;
a step (exposure step) of irradiating the photosensitive coloring composition layer with light having a wavelength of 300 nm or shorter to be exposed in a pattern shape; and
a step (development step) of forming a pixel by removing a non-exposed portion of the photosensitive coloring composition layer by development. Hereinafter, the respective steps will be described.

(Photosensitive Coloring Composition Layer Forming Step)

A photosensitive coloring composition layer having an optical density of 1.6 or higher with respect to light having a wavelength of 248 nm is formed on a support using a photosensitive coloring composition including a coloring material and a curable compound.

The optical density of the photosensitive coloring composition layer can be adjusted to be in the above-described range by appropriately adjusting the kind and concentration of the coloring material and the thickness of the photosensitive coloring composition layer. The optical density of the photosensitive coloring composition layer is preferably 1.8 or higher and more preferably 2.0 or higher. The upper limit is not particularly limited and may be 3.5 or lower.

It is preferable that photosensitive coloring composition is the above-described photosensitive coloring composition according to the embodiment of the present invention, The thickness of the photosensitive adoring composition layer is preferably 300 to 1,000 nm. The lower limit is preferably 400 nm or more and more preferably 500 nm or more. The upper limit is preferably 800 nm or less and more preferably 600 nm or less.

Examples of the support include a substrate formed of a material such as silicon, non-alkali glass, soda glass, PYREX (registered trade name) glass, or quartz glass. In addition, for example, an InGaAs substrate is preferably used. In addition, a charge coupled device (CCD), a complementary metal-oxide semiconductor (CMOS), a transparent conductive film, or the like may be formed on the support. In addition, a black matrix that separates pixels from each other may be formed on the support. In addition, optionally, an undercoat layer may be provided on the support to improve adhesiveness with a layer above the support, to prevent diffusion of materials, or to make a surface of the substrate flat.

As a method of applying the photosensitive coloring composition to the support, a well-known method can be used. Examples of the well-known method include: a drop casting method; a slit coating method; a spray coating method; a roll coating method; a spin coating method; a cast coating method; a slit and spin method; a pre-wetting method (for example, a method described in JP2009-145395A); various printing methods including jet printing such as an ink jet method (for example, an on-demand method, a piezoelectric method, or a thermal method) or a nozzle jet method, flexographic printing, screen printing, gravure printing, reverse offset printing, and metal mask printing; a transfer method using a mold or the like; and a nanoimprint method. The application method using an ink jet method is not particularly limited, and examples thereof include a method (in particular, pp. 115 to 133 described in “Extension of Use of Ink Jet—Infinite Possibilities in Patent-” (February, 2005, S.B. Research Co., Ltd.) and methods described in JP2003-262716A, JP2003-185831A, JP2003-261827A, JP2012-126830A, and JP2006-169325A. In addition, the details of the method of applying the resin composition can be found in WO2017/030174A and WO2017/018419A, the contents of which are incorporated herein by reference.

The photosensitive coloring composition may be dried (pre-baked) after being applied to the support. In a case where pre-baking is performed, the pre-baking temperature is preferably 150° C. or lower, more preferably 120° C. or lower, and still more preferably 110° C. or lower. The lower limit is, for example, 50° C. or higher or 80° C. or higher. The pre-baking time is preferably 10 to 3000 seconds, more preferably 40 to 2500 seconds, and still more preferably 80 to 2200 seconds. Drying can be performed using a hot plate, an oven, or the like.

(Exposure Step)

Next, the photosensitive coloring composition layer formed on the support as described above is irradiated with light having a wavelength of 300 nm or shorter to be exposed in a pattern shape. By exposing the photosensitive coloring composition layer through a mask having a predetermined mask pattern, the photosensitive coloring composition layer can be exposed in a pattern shape. As a result, the exposed portion of the photosensitive coloring composition layer can be cured.

The light used for exposure may be light having a wavelength of 300 nm or shorter and preferably light having in a wavelength range of 180 to 300 nm. Specific examples of the light include a KrF ray (wavelength: 248 nm) and an ArF ray (wavelength: 193 nm). Among these, for example, a KrF ray (wavelength: 248 nm) is preferable from the viewpoint that a bond to the coloring material or the curable compound in the photosensitive coloring composition is not likely to be cut. In addition, it is preferable that the exposure is performed using a KrF scanner exposure device. In this aspect, the alignment accuracy of exposure is excellent, and a fine pixel is likely to be formed.

For example, the exposure dose is preferably 1 to 2000 mJ/cm². The upper limit is preferably 1000 mJ/cm² or Iowa and more preferably 500 mJ/cm² or lower. The lower limit is preferably 5 mJ/cm² or higher, more preferably 10 mJ/cm² or higher, and still more preferably 20 mJ/cm² or higher.

The oxygen concentration during exposure can be appropriately selected. The exposure may be performed not only in air but also in a low-oxygen atmosphere having an oxygen concentration of 19 vol % or lower (for example, 15 vol %, 5 vol %, or substantially 0 vol %) or in a high-oxygen atmosphere having an oxygen concentration of higher titan 21 vol % (for example, 22 vol %, 30 vol %, or 50 vol %). In addition, the exposure illuminance can be appropriately set and typically can be selected in a range of 1000 W/m² to 100000 W/m² (for example, 5000 W/m², 15000 W/m², or 35000 W/m²). Conditions of the oxygen concentration and conditions of the exposure illuminance may be appropriately combined. For example, conditions are oxygen concentration: 10 vol % and illuminance: 10000 W/m², or oxygen concentration: 35 vol % and illuminance: 20000 W/m².

(Development Step)

Next, after the exposure step, a pixel (pattern) is formed by removing a non-exposed portion of the photosensitive coloring composition layer by development. The non-exposed portion of the photosensitive coloring composition layer can be removed by development using a developer. As a result, the non-exposed portion of the photosensitive coloring composition layer in the exposure step is eluted into the developer, and only the portion that is photocured in the above-described exposure step remains on the support. As the developer, an alkali developer which does not cause damages to a solid image pickup clement as an underlayer, a circuit or the like is desired. For example, the temperature of the developer is preferably 20°60 C. to 30° C. The development time is preferably 20 to 180 seconds. In addition, in order to further improve residue removing properties, a step of shaking the developer off per 60 seconds and supplying a new developer may be repeated multiple times.

Examples of the alkaline agent used as the developer include: an organic alkaline compound such as ammonia water, ethylamine, diethylamine, dimethylethanolamine, diglycolamine, diethanolamine, hydroxyamine, ethylenediamine, tetramethylammonium hydroxide, tetraethylammonium hydroxide, tetrapropylammonium hydroxide, tetrabutylammonium hydroxide, ethyltrimethylammonium hydroxide, benzyltrimethylammonium hydroxide, dimethyl bis(2-hydroxyethyl)ammonium hydroxide, choline, pyrrole, piperidine, or 1,8-diazabicyclo[5.4.0]-7-undecene; and an inorganic alkaline compound such as sodium hydroxide, potassium hydroxide, sodium carbonate, sodium bicarbonate, sodium silicate, or sodium metasilicate. From the viewpoints of environment and safety, it is preferable that the alkaline agent is a compound having a high molecular weight. As the developer, an alkaline aqueous solution in which the above alkaline agent is diluted with pure water is preferably used. A concentration of the alkaline agent in the alkaline aqueous solution is preferably 0.001 to 10 mass % and more preferably 0.01 to 1 mass %. In addition, a surfactant may be added to the developer. From the viewpoint of easiness of transport, storage, and the like, the developer may be obtained by temporarily preparing a concentrated solution and diluting the concentrated solution to a necessary concentration during use. The dilution factor is not particularly limited and, for example, can be set to be in a range of 1.5 to 100 times. In a case where a developer including the alkaline aqueous solution is used, it is preferable that the layer is rinsed with pure water after development.

After the development and drying, an additional exposure treatment or a heating treatment (post-baking) can also be performed. The additional exposure treatment or the post-baking is a treatment which is performed after development to completely cure the film. In a case where the additional exposure treatment is performed, as light used for the exposure, for example, a g-ray, a h-ray, or an i-ray is preferable, and an i-ray is more preferable. In addition, a combination of the above-described rays may be used. Examples of the light source include an ultrahigh pressure mercury lamp, a metal halide lamp, and a laser light source. The illuminance is preferably 500 to 100000 W/m². For example, the exposure dose is preferably 500 to 10000 mJ/cm². In addition, in a case where post-baking is performed, for example, the post-baking temperature is preferably 50° C. to 240° C. From the viewpoint of curing the film, the post-baking temperature is more preferably 180° to 230° C.

It is preferable that the thickness of the pixel (pattern) to be formed is appropriately selected depending on the kind of the pixel. For example, the thickness of the pixel is preferably 2.0 μm or less, more preferably 1.0 μm or less, and still more preferably 0.3 to 1.0 μm. The upper limit is preferably 0.8 μm or less and more preferably 0.6 μm or less. The lower limit value is preferably 0.4 μm or more.

In addition, it Is preferable that the size (line width) of the pixel (pattern) to be formed is selected depending on the use or the kind of the pixel. For example, the size of the pixel is preferably 2.0 μm or less. The upper limit is preferably 1.0 μm or less and more preferably 0.9 μm or less. The lower limit value is preferably 0.4 μm or more.

In a case where an optical filter including plural kinds of pixels is manufactured, at least one kind of pixel may be formed through the above-described steps. A second or subsequent kind of pixel can also be formed through the above-described steps. Light used for the exposure during the formation of the second or subsequent kind of pixel may be light having a wavelength of 300 nm or shorter or may be light having a wavelength of longer than 300 nm (for example, an i-ray).

### EXAMPLES

Hereinafter, the present invention will be described in detail using examples. Materials, used amounts, ratios, treatment details, treatment procedures, and the like shown in the following examples can be appropriately changed within a range not departing from the scope of the present invention. Accordingly, the scope of the present invention is not limited to the following specific examples. Unless specified otherwise, “part(s)” and “%” represent “part(s) by mass” and “mass %”.

<Measurement of Weight-Average Molecular Weight (Mw)of Resin>

The weight-average molecular weight of the resin can be measured under the following conditions by gel permeation chromatography (GPC).

Kind of column: a column in which TOSOH TSK gel Super HZM-H, TOSOH TSK gel Super HZ4000, and TOSOH TSK gel Super HZ2000 were linked to each other

Developing solvent: tetrahydrofuran

Column temperature: 40° C.

Flow rate (sample injection volume): 1.0 μL (sample concentration: 0.1 mass %)

Device name: HLC-8220 GPC (manufactured by Tosoh Corporation)

Detector: refractive index (RI) detector

Calibration curve base resin: a polystyrene resin

<Preparation of Photosensitive Coloring Composition>

The following raw materials were mixed, and the obtained mixture was filtered through a nylon filter (manufactured by Pall Corporation) having a pore size of 0.45 μm. This way, photosensitive coloring compositions having a concentration of solid contents of 20 mass % were prepared. The concentration of solid contents of each of the photosensitive coloring compositions was adjusted by adjusting the mixing amount of propylene glycol monomethyl ether acetate (PGMEA).

TABLE 1

| | | Pigment | | Polymerizable | Photopolymerization | | | |
|---|---|---|---|---|---|---|---|---|
| | | Dispersion | Resin | Monomer | Initiator | Surfactant | Additive | Solvent |
| Examples 1 | Kind | A1 | B1 | M1 | I1 | W1 | | PGMEA |
| | Mixing Amount | 550 | 8 | 11 | 5 | 0.1 | | Balance |
| Examples 2 | Kind | A1 | B1 | M1 | I1/I2 | W1 | | PGMEA |
| | Mixing Amount | 380 | 9 | 11 | 4/1 | 0.1 | | Balance |
| Examples 3 | Kind | A1 | B1 | M1 | I1/I2 | W1 | | PGMEA |
| | Mixing Amount | 800 | 7 | 11 | 3/2 | 0.1 | | Balance |
| Examples 4 | Kind | A1 | B1 | M1 | I1/I2 | W2 | | PGMEA |
| | Mixing Amount | 550 | 8 | 11 | 4/1 | 0.1 | | Balance |
| Examples 5 | Kind | A1 | B1 | M1 | I1/I2 | W1 | | PGMEA |
| | Mixing Amount | 550 | 8 | 11 | 4/1 | 0.1 | | Balance |
| Examples 6 | Kind | A1 | B1 | M1 | I1/I2 | W2 | T1 | PGMEA |
| | Mixing Amount | 550 | 8 | 11 | 4/1 | 0.1 | 2 | Balance |
| Examples 7 | Kind | A1 | B2 | M1 | I1/I2 | W1 | | PGMEA |
| | Mixing Amount | 550 | 8 | 11 | 4/1 | 0.1 | | Balance |
| Examples 8 | Kind | A1 | B3 | M1 | I1/I2 | W1 | | PGMEA |
| | Mixing Amount | 550 | 8 | 11 | 4/1 | 0.1 | | Balance |
| Examples 9 | Kind | A1 | B1/B3 | M1 | I1/I2 | W1 | | PGMEA |
| | Mixing Amount | 550 | 4/4 | 11 | 4/1 | 0.1 | | Balance |
| Examples 10 | Kind | A1 | B1 | M1/M2 | I1/I2 | W1 | | PGMEA |
| | Mixing Amount | 550 | 8 | 6/5 | 4/1 | 0.1 | | Balance |
| Examples 11 | Kind | A1 | B1 | M1 | I3 | W2 | T1 | PGMEA |
| | Mixing Amount | 550 | 8 | 11 | 5 | 0.1 | 2 | Balance |
| Examples 12 | Kind | A1 | B1 | M1 | I4 | W1 | | PGMEA |
| | Mixing Amount | 550 | 8 | 11 | 5 | 0.1 | | Balance |
| Examples 13 | Kind | A1 | B1 | M1 | I5 | W1 | | PGMEA |
| | Mixing Amount | 550 | 8 | 11 | 5 | 0.1 | | Balance |
| Examples 14 | Kind | A1 | B1 | M1 | | W1 | T1 | PGMEA |
| | Mixing Amount | 550 | 4 | 11 | | 0.1 | 2 | Balance |
| Examples 15 | Kind | A2 | B1 | M1 | I1 | W1 | | PGMEA |
| | Mixing Amount | 500 | 8 | 11 | 5 | 0.1 | | Balance |
| Examples 16 | Kind | A3 | B1 | M1 | I1 | W1 | | PGMEA |
| | Mixing Amount | 500 | 8 | 11 | 5 | 0.1 | | Balance |
| Examples 17 | Kind | A4 | B1 | M1 | I1 | W1 | | PGMEA |
| | Mixing Amount | 500 | 8 | 11 | 5 | 0.1 | | Balance |
| Examples 18 | Kind | A5 | B1 | M1 | I1 | W1 | | PGMEA |
| | Mixing Amount | 500 | 8 | 11 | 5 | 0.1 | | Balance |
| Examples 19 | Kind | A6 | B1 | M1 | I1 | W1 | | PGMEA |
| | Mixing Amount | 500 | 8 | 11 | 5 | 0.1 | | Balance |
| Examples 20 | Kind | A7 | B1 | M1 | I1 | W1 | | PGMEA |
| | Mixing Amount | 500 | 8 | 11 | 5 | 0.1 | | Balance |
| Comparative | Kind | A1 | B1 | M1 | I1 | W1 | | PGMEA |
| Example 1 | Mixing Amount | 150 | 8 | 11 | 5 | 0.1 | | Balance |

The raw materials shown above in the table are as follows.

(Pigment Dispersion)

A1: A Pigment Dispersion Prepared Using the Following Method

10.7 parts by mass of C.I. Pigment (been 58, 2.7 parts by mass of C.I. Pigment Yellow 185, 1.3 parts by mass of a pigment derivative Y, 5.3 parts by mass of a dispersant D1, and 80 parts by mass of propylene glycol monomethyl ether acetate (PGMEA) were prepared to prepare a mixed solution, 230 parts by mass of zirconia beads having a diameter of 0.3 mm was further added to the mixed solution, the mixed solution was dispersal using a paint shaker for 3 hours, and the beads were separated by filtration. As a result, a pigment dispersion A1 was prepared. In this the pigment dispersion A1, live concentration of solid contents was 20 mass %, and the pigment (coloring material) content was 13.4 mass %.

Pigment Derivative Y1: A Compound Having the Following Structure

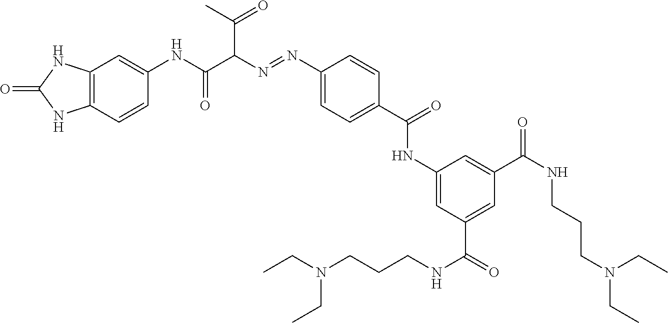 [SMILES: CCN(CC)CCCNC(=O)c1cc(NC(=O)c2ccc(/N=N/C(C(C)=O)C(=O)Nc3ccc4[nH]c(=O)[nH]c4c3)cc2)cc(C(=O)NCCCN(CC)CC)c1]

Dispersant D1: A Resin Having the Following Structure (Mw=26000; A Numerical Value Added to a Main Chain Represents a Molar Ratio, and a Numerical Value Added to a Side Chain Represents the Number of Repeating Units)

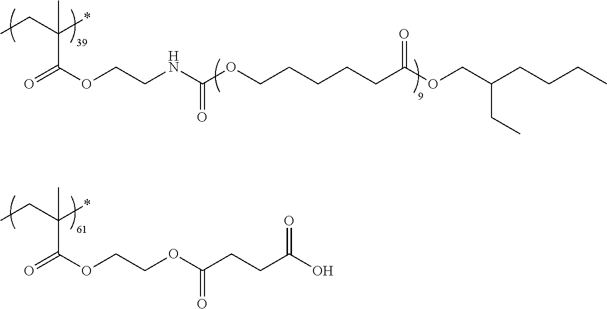

A2: A Pigment Dispersion Prepared Using the Following Method

9 parts by mass of C.I. Pigment Green 36, 6 parts by mass of C.I. Pigment Yellow 150, 2.5 parts by mass of the pigment derivative Y1, 5 parts by mass of the dispersant D1, and 77.5 parts by mass of propylene glycol monomethyl ether acetate (PGMEA) were prepared to prepare a mixed solution, 230 pans by mass of zirconia beads having a diameter of 0.3 mm was further added to the mixed solution, the mixed solution was dispersed using a paint shaker for 3 hours, and the beads were separated by filtration. As a result, a pigment dispersion A2 was prepared. In this the pigment dispersion A2, the concentration of solid contents was 22.5 mass %, and the coloring material content was 15 mass %.

A3: A Pigment Dispersion Prepared Using the Following Method

9 parts by mass of C.I. Pigment Green 58. 6 parts by mass of C.I. Pigment Yellow 138, 2.5 parts by mass of the pigment derivative Y1, 5 parts by mass of the dispersant D1, and 77.5 parts by mass of propylene glycol monomethyl ether acetate (PGMEA) were prepared to prepare a mixed solution, 230 parts by mass of zirconia beads having a diameter of 0.3 mm was further added to the mixed solution, the mixed solution was dispersed using a paint shaker for 3 hours, and the beads were separated by filtration. As a result, a pigment dispersion A3 was prepared. In this the pigment dispersion A3, the concentration of solid contents was 22.5 mass %, and the coloring material content was 15 mass %.

A4. A Pigment Dispersion Prepared Using the Following Method

10.5 parts by mass of CX Pigment Red 254, 4.5 parts by mass of C.I. Pigment Yellow 139, 2.0 parts by mass of the pigment derivative Y1, 5.5 parts by mass of the dispersant D1, and 77.5 parts by mass of propylene glycol monomethyl ether acetate (PGMEA) were prepared to prepare a mixed solution, 230 parts by mass of zirconia beads having a diameter of 0.3 mm was further added to the mixed solution, the mixed solution was dispersed using a paint shaker for 3 hours, and the beads were separated by filtration. As a result, a pigment dispersion A4 was prepared. In this the pigment dispersion A4, the concentration of solid contents was 22.5 mass %, and the coloring material content was 15 mass %.

A5: A Pigment Dispersion Prepared Using the Following Method

10.5 parts by mass of C.I. Pigment Red 177, 4.5 parts by mass of C.I. Pigment Yellow 139. 2.0 parts by mass of the pigment derivative Y2, 5.5 parts by mass of the dispersant D2, and 77.5 pans by mass of propylene glycol monomethyl ether acetate (PGMEA) were prepared to prepare a mixed solution, 230 parts by mass of zirconia beads having a diameter of 0.3 mm was further added to the mixed solution, the mixed solution was dispersed using a paint shaker for 3 hours, and the beads were separated by filtration. As a result, a pigment dispersion A5 was prepared. In this the pigment dispersion A5, the concentration of solid contents was 22.5 mass %, and the coloring material content was 15 mass %.

Pigment Derivative Y2: A Compound Having the Following Structure

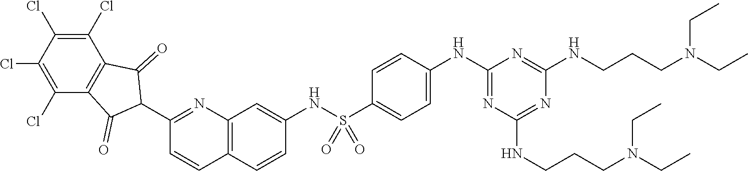 [SMILES: CCN(CC)CCCNc1nc(NCCCN(CC)CC)nc(Nc2ccc(S(=O)(=O)Nc3ccc4ccc(C5C(=O)c6c(Cl)c(Cl)c(Cl)c(Cl)c6C5=O)nc4c3)cc2)n1]

Dispersant D2: A Resin Having the Following Structure

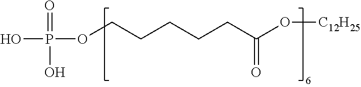

A6: A Pigment Dispersion Prepared Using the Following Method

12 parts by mass of C.I. Pigment Blue 15:6,3 parts by mass of C.I. Pigment Violet 23, 2.7 parts by mass of the pigment derivative Y1, 4.8 parts by mass of the dispersant D1, and 77.5 parts by mass of propylene glycol monomethyl ether acetate (PGMEA) were prepared to prepare a mixed solution, 230 parts by mass of zirconia beads having a diameter of 0.3 mm was further added to the mixed solution, the mixed solution was dispersed using a paint shaker for 3 hours, and the beads were separated by filtration. As a result, a pigment dispersion A6 was prepared. In this the pigment dispersion A6, the concentration of solid contents was 22.5 mass %, and the coloring material content was 15 mass %.

A7: A Pigment Dispersion Prepared Using the Following Method

12 parts by mass of C.I. Pigment Blue 15:6, 3 parts by mass of a V dye 1 described in paragraph “0292” of JP2015-041058A, 2.7 parts by mass of the pigment derivative Y1, 4.8 parts by mass of the dispersant D1, and 77.5 parts by mass of propylene glycol monomethyl ether acetate (PGMEA) were prepared to prepare a mixed solution, 230 parts by mass of zirconia beads having a diameter of 0.3 mm was further added to the mixed solution, the mixed solution was dispersed using a paint shaker for 3 hours, and the beads were separated by filtration. As a result, a pigment dispersion A7 was prepared. In this the pigment dispersion A7, the concentration of solid contents was 22.5 mass %, and the coloring material content was 15 mass %.

(Resin)

B1: a resin having the following structure (a numerical value added to a main chain represents a molar ratio; Mw=10,000, acid value=70 mgKOH/g, C═C value=1.4 mmol/g)

B2: a resin having the following structure (a numerical value added to a main chain represents a molar ratio; Mw=40,000, acid value=95 mgKOH/g, C═C value=9.2 mmol/g)

B3: a resin having the following structure (a numerical value added to a main chain represents a molar ratio; Mw=30,000, acid value=110 mgKOH/g, C═C value=0 mmol/g)

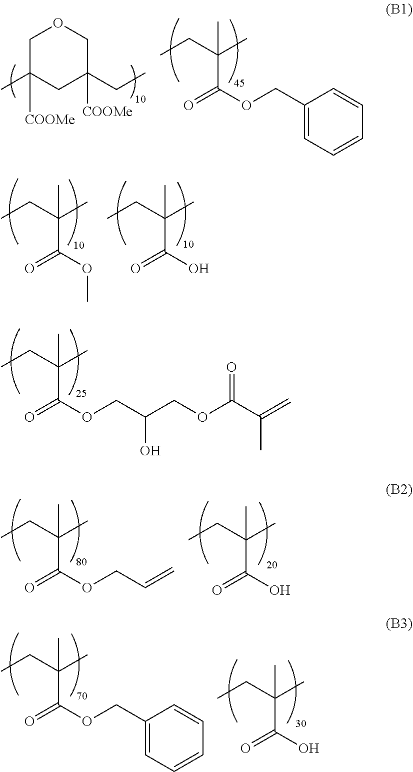

(Polymerizable Monomer)

M1: a compound having the following structure (C═C value=11.4 mmol/g)

M2: a compound having the following structure (C═C value=10.4 mmol/g)

M3: a compound having the following structure (C═C value=5.4 mmol/g)

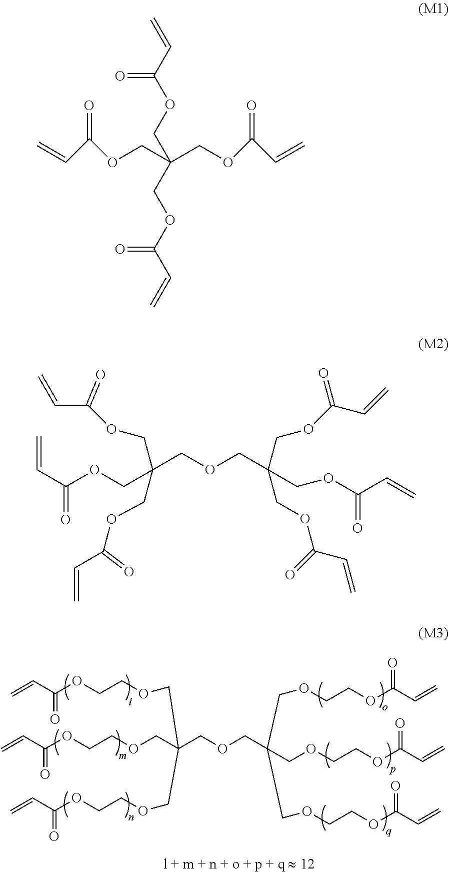

(Photopolymerization Initiator)

I1: IRGACURE-OXE01 (manufactured by BASF SE, an oxime compound)

I2: a compound (oxime compound) having the following structure

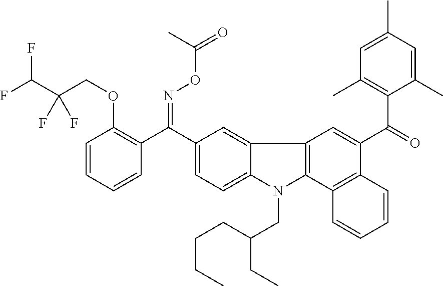 [SMILES: CCCCC(CC)Cn1c2ccc(/C(=N\OC(C)=O)c3ccccc3OCC(F)(F)C(F)F)cc2c2cc(C(=O)c3c(C)cc(C)cc3C)c3ccccc3c21]

I3: IRGACURE-184 (manufactured by BASF SE, an α-hydroxyalkylphenone compound)

I4: IRGACURE-TPO (manufactured by BASF SE, an acylphosphine compound)

I5: a compound (benzopinacol) having the following structure

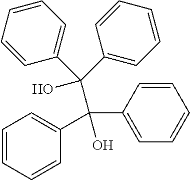 [SMILES: OC(c1ccccc1)(c1ccccc1)C(O)(c1ccccc1)c1ccccc1]

(Surfactant)

W1: KF-6002 (manufactured by Shin-Etsu Chemical Co., Ltd.)

W2: the following mixture (Mw=14000, in the following formula, representing the proportion of a repeating unit is mol %)

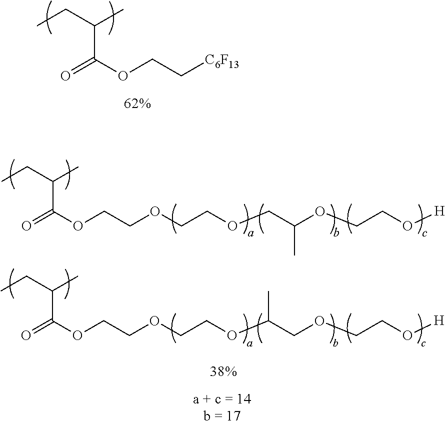

(Additives)

T1: EHPE 3150 (manufactured by Daicel Corporation, a compound having an epoxy group)

T2: a compound (silane coupling agent) having the following structure

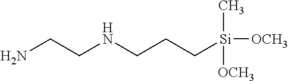

(Solvent)

PGMEA: propylene glycol monomethyl ether acetate

<Measurement of Optical Density (OD Value)>

The above-described photosensitive coloring composition was applied to a glass substrate using a spin coating method. Next, the coating film was heated using a hot plate at 100° C. for 2 minutes such that a film having a thickness of 0.5 μm was formed. The obtained film was irradiated with light having a wavelength of 248 nm, and the transmittance thereof was measured using a spectrophotometer (UV4100, manufactured by Hitachi High-Technologies Corporation) to measure an optical density (OD value) at a wavelength of 248 nm.

<Manufacturing of Optical Filter>

The photosensitive coloring composition B or the photosensitive coloring composition C was applied to a 1 cm² area of a silicon wafer using a spin coating method such that the thickness of the film after post-baking was 0.5 μm. Next, the coating film was post-baked using a hot plate at 100° C. for 2 minutes. Next, using a KrF scanner exposure device (FPA-6000ES6a, manufactured by Canon Inc.), the coating film was exposed to a KrF ray at an exposure dose of 200 mJ/cm² through a mask having a Bayer pattern for forming a pixel having a size of 1 μm×1 μm. Next, puddle development was performed at 23° C. for 60 seconds using a tetramethylammonium hydroxide (TMAH) 0.3 mass % aqueous solution. Next, the coating film was rinsed by spin showering and was cleaned with pure water. Next, the coating film was heated using a hot plate at 200° C. for 5 minutes to obtain a pixel (pattern).

<Evaluation of Rectangularity>

A cross-section of the formed pixel (pattern) was observed using a scanning electron microscope (SEM).

An angle between a lower side and a lateral side of the pixel was defined as follows,

a: 88° to 92°

b: 80° to 88° or 92° to 100°

c: other than the above-described ranges

An angle between an upper side and a lateral side of the pixel was defined as follows,

a′: 87° to 93°

b′: 78° to 87° or 93° to 102°

c′: other than the above-described ranges

In this case, rectangularity was evaluated based on the following standards.

A: a and a′ were satisfied

B: a and b′, or a′ and b were satisfied

C: b and b′ were satisfied

D: either c or c′ was satisfied

<Evaluation of Adhesiveness>

A plane of the formed pixel (pattern) was observed using an optical microscope, and the adhesiveness of the pixel (pattern) was evaluated based on the following standards.

A: regarding the 1 μm×1 μm pixels (patterns) formed in the 1 cm² area, peeling was not observed

B: regarding the 1 μm×1 μm pixels (patterns) formed in the 1 cm² area, peeling was observed in the pixels on the outermost circumference of the 1 cm² area, but peeling was not observed in the pixels formed inside the above-described area

C: regarding the 1 μm×1 μm pixels (patients) formed in the 1 cm² area, peeling was observed in a number of pixels that was more than 0% and 10% or less of all the pixels formed inside the above-described area

D: regarding the 1 μm×1 μm pixels (patterns) formed in the 1 cm² area, peeling was observed in a number of pixels that was more than 10% of all the pixels formed inside the above-described area

TABLE 2

| | Evaluation | | | |
|---|---|---|---|---|
| | OD | Coloring Material | Rectan- | Adhe- |
| | Value | Concentration (mass %) | gularity | siveness |
| Examples 1 | 2.1 | 55 | A | A |
| Examples 2 | 1.9 | 50 | B | A |
| Examples 3 | 2.3 | 58 | A | A |
| Examples 4 | 2.1 | 55 | B | B |
| Examples 5 | 2.1 | 55 | C | C |
| Examples 6 | 2.1 | 55 | A | A |
| Examples 7 | 2.1 | 55 | A | A |
| Examples 8 | 2.1 | 55 | B | C |
| Examples 9 | 2.1 | 55 | B | B |
| Examples 10 | 2.1 | 55 | A | B |
| Examples 11 | 2.1 | 55 | B | B |
| Examples 12 | 2.1 | 55 | B | B |
| Examples 13 | 2.1 | 55 | B | B |
| Examples 14 | 2.1 | 55 | A | A |
| Examples 15 | 1.8 | 55 | A | A |
| Examples 16 | 2.2 | 55 | A | A |
| Examples 17 | 2.1 | 55 | B | B |
| Examples 18 | 2 | 55 | B | B |
| Examples 19 | 2.3 | 55 | B | A |
| Examples 20 | 2.4 | 55 | B | A |
| Comparative | 1.4 | 34 | D | D |
| Example 1 | | | | |

As shown in the table, in Examples, a pixel having higher rectangularity and adhesiveness than Comparative Examples was able to be formed.

Even in a case where the same amount of C.I. Pigment Red 264 was used instead of C.I. Pigment Red 254 in the pigment dispersion A4, the same effects as those of Example 17 were obtained.

Even in a case where a squarylium compound was added as the infrared absorbing colorant in each of Examples 1 to 20, the same effects as those of each of Examples were obtained.

What is claimed is:

1. A photosensitive coloring composition comprising:
a coloring material; and
a curable compound,
wherein the photosensitive coloring composition is used for exposure to light having a wavelength of 300 nm or shorter, and
in a case where a film having a thickness of 0.5 μm after drying is formed using the photosensitive coloring composition, an optical density of the film with respect to light having a wavelength of 248 nm is 1.6 or higher.

2. The photosensitive coloring composition according to claim 1, wherein a content of the coloring material is 50 mass % or higher with respect to a total solid content of the photosensitive coloring composition.

3. A photosensitive coloring composition comprising:
a coloring material; and
a curable compound,
wherein the photosensitive adoring composition is used for exposure to light having a wavelength of 300 nm or shorter, and
a content of the coloring material is 50 mass % or higher with respect to a total solid content of the photosensitive coloring composition.

4. The photosensitive coloring composition according to claim 1, which is a photosensitive coloring composition for exposure to a KrF ray.

5. The photosensitive coloring composition according to claim 1,
wherein the curable compound includes a polymerizable monomer, and
a polymerizable group value of the polymerizable monomer is 10.5 mmol/g or higher.

6. The photosensitive coloring composition according to claim 5, further comprising: a photopolymerization initiator.

7. The photosensitive coloring composition according to claim 6,
wherein the photopolymerization initiator is at least one compound selected from an alkylphenone compound, an acylphosphine compound, a benzophenone compound, a thioxanthone compound, a triazine compound, a pinacol compound, or an oxime compound.

8. The photosensitive coloring composition according to claim 3,
wherein the curable compound includes a polymerizable monomer, and
a polymerizable group value of the polymerizable monomer is 10.5 mmol/g or higher.

9. The photosensitive coloring composition according to claim 8, further comprising: a photopolymerization initiator.

10. The photosensitive coloring composition according to claim 9,
wherein the photopolymerization initiator is at least one compound selected from an alkylphenone compound, an acylphosphine compound, a benzophenone compound, a thioxanthone compound, a triazine compound, a pinacol compound, or an oxime compound.

11. The photosensitive coloring composition according to claim 1,
wherein the coloring material includes a green colorant.

12. The photosensitive coloring composition according to claim 11,
wherein a content of the green colorant is 50 mass % or higher with respect to a total mass of the coloring material.

13. The photosensitive coloring composition according to claim 3,
wherein the coloring material includes a green colorant

14. The photosensitive coloring composition according to claim 13,
wherein a content of the green colorant is 50 mass % or higher with respect to a total mass of the coloring material. 15. A method of manufacturing an optical filter, the method comprising:
forming a photosensitive coloring composition layer having an optical density of 1.6 or higher with respect to light having a wavelength of 248 nm on a support using a photosensitive coloring composition including a coloring material and a curable compound; irradiating the photosensitive coloring composition layer with light having a wavelength of 300 nm or shorter to be exposed in a pattern shape; and forming a pixel by removing a non-exposed portion of the photosensitive coloring composition layer by development. 16. The method of manufacturing an optical filter according to claim 15,
wherein the exposure step is performed using a KrF scanner exposure device. 17. The method of manufacturing an optical filter according to claim 15,
wherein the photosensitive coloring composition is the photosensitive coloring composition according to claim 1.
